(19) United States
(12) Patent Application Publication
(10) Pub. No.: US 2002/0003305 A1
(43) Pub. Date: Jan. 10, 2002

(54) Semiconductor integrated circuit device including an interlayer insulating film formed under a bonding pad and arranged to prevent peeling of the bonding pad

(76) Inventors: Masashi Umakoshi, Tokyo (JP); Naokatsu Suwanai, Tokyo (JP); Atsushi Ogishima, Tokyo (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/934,596

(22) Filed: Aug. 23, 2001

Related U.S. Application Data
(63) Continuation of application No. 09/034,338, filed on Mar. 4, 1998.

(30) Foreign Application Priority Data
Mar. 4, 1997 (JP) 9-49085

(51) Int. Cl. H01L 23/48; H01L 23/52; H01L 29/40

(52) U.S. Cl. 257/760

(57) ABSTRACT

A dummy interconnection is formed below a bonding pad formed on an interlayer insulating film composed of a silicon oxide film, an SOG film, and a silicon oxide film. The adhesion of layers is improved by increasing a direct contact area between these silicon oxide films formed of the same material.

### BACKGROUND OF THE INVENTION

This invention relates to a semiconductor integrated circuit device and fabrication process thereof, and, particularly, to a technique which is effective when used for a semiconductor integrated circuit device which comprises a/semiconductor chip, whose upper and lower interconnections are flattened there between by an insulating layer containing a spin-on-glass (SOG) film, sealed in a tape carrier package (TCP).

A recently developed large-capacity DRAM (dynamic random access memory) adopts a stacked capacitor structure having a capacitive element (capacitor) for information storage disposed above a MISFET (metal-insulator semiconductor field effect transistor) for the selection of a memory cell in order to make up for a decrease in m the amount of accumulated charge of the capacitor caused by the miniaturization of a memory cell. A stepped portion (difference in elevation) corresponding to almost the height of the capacitor therefore appears between a memory array and its peripheral circuit. When an interconnection (wiring line) is formed on such a stepped portion, an etching residue appears thereon, or a focus deviation of the exposure light occurs at the time of photo-lithography, which disturbs the processing of the interconnection with good precision, thereby causing a short-circuit and the like.

To solve such a problem, a technique of for flattening an interlayer insulating film which electrically insulates a lower interconnection layer from an upper interconnection layer becomes indispensable.

Since it is generally difficult to flatten an interlayer insulating film by using only one insulating film, it is a common practice to deposit a silicon oxide film on an interconnection using the CVD (chemical vapor deposition) method and then to embed a spin-on-glass (SOG) film in a recessed portion of the silicon oxide film formed in a space between interconnections. For example, Japanese Patent Application Laid-Open No. HEI 3-72693 is describes a flattening technique which comprises depositing a silicon oxide film on an interconnection by the plasma CVD method, spin coating an SOG film thereon, densifying the layer by heat treatment (baking), flattening the surface of the densified layer by etching back, and then depositing thereon a second silicon oxide film by the plasma CVD method.

### SUMMARY OF THE INVENTION

The present inventor has found that upon sealing such a semiconductor chip, which has two vertically disposed interconnection layers flattened therebetween by using an insulating film containing an SOG film, in an LSI package, a bonding pad together with a portion of an insulating film disposed thereunder peels at the interface with the SOG film due to an impact which occurs at the time when a lead is bonded on a bonding pad formed on the principal surface (a surface to have a device formed thereon) of the semiconductor chip.

As illustrated in FIG. 42 (a), an SOG film 100 tends to remain in a large and flat region as a region below a bonding pad BP even by etch back, and, in such a case, peeling tends to occur at the interface between the SOG film 100 and a silicon oxide film 101a or 101b. This causes deterioration in the adhesion of the bonding pad BP and, in the worst case, the bonding pad BP peels together with the silicon oxide film 101b disposed thereunder at the interface with the SOG film 100, as illustrated in FIG. 42(b). In a region (memory array, direct peripheral circuit region) wherein many interconnections 120 have been formed, on the other hand, an SOG film 100 is embedded in a recess portion of a silicon oxide film 101a, the recess portion having appeared in a space between interconnections, and therefore does not remain on the interconnections 120, as illustrated in FIG. 42(c) In a region of close interconnections, as illustrated in FIG. 42(c), when the SOG film 100 is formed to be embedded in a recess portion of the silicon oxide film 101a appearing in a space between interconnections, the SOG film 100 tends to remain, as illustrated in FIG. 42(a), in a large and flat region, such as a region below the bonding pad.

Indicated at numeral 110 is a final passivation film.

As examples of the package having a semiconductor chip, on which a memory LSI, such as DRAM, has been formed, sealed therein, there are a TCP (tape carrier package), TSOP (thin small outline package), and TSOJ (thin small outline J-lead package). Among them, the TCP formed by the fabrication method called a “post-step bumping method” tends to undergo peeling, as described above, because of a strong impact applied to the bonding pad.

A TCP is ordinarily fabricated by disposing a semi-conductor chip in a device hole of an insulating tape having a lead formed on one side thereof and bonding one end portion of the lead onto a bump electrode which has been preliminarily formed on a pad of the semiconductor chip in a prior step (wafer process), thereby electrically connecting the lead and the bonding pad—In this case, the bonding pad does not peel so easily because an impact is applied to the bonding pad only once.

In the “post-step bump method”, on the other hand, an Au ball 102A is bonded onto a bonding pad BP, as illustrated in FIG. 43(a), by using a wire bonding apparatus (bump installing step). Then, the surface of the Au ball 102A is flattened by a tool 103, as illustrated in FIG. 43(b), to form a bump electrode 102 having an even height (flattening step) As illustrated in FIG. 43(c) one end portion (inner lead portion) of the lead 104 is then bonded onto the bump electrode 102, whereby the lead 104 and the bonding pad BP are electrically connected (lead bonding step).

The above-described “post-step bump method” has the advantage that, upon fabrication of a memory module or the like by stacking TCP on a printed circuit board, a chip selecting signal can be detected according to the presence or absence of a bump electrode on a bonding pad, which facilitate the designing of the memory module using the TCP. According to the above method, however, impacts are applied to the bonding pad three times in total, more specifically, upon bonding of an Au ball on the bonding pad, upon formation of a bump electrode by flattening the surface of the Au ball using a tool and upon bonding of a lead on the bump electrode, which applies a large stress on an insulating film below the pad, resulting in deterioration in the adhesion between insulating film thereby tending to cause peeling at the interface of the SOG film 100 as illustrated in FIGS. 42(a) and (b).

### SUMMARY OF THE INVENTION

An object of the present invention is to provide a technique capable of preventing the peeling of a bonding pad which occurs in a step for sealing a semiconductor chip, which has two vertically-disposed interconnections flattened therebetween by an insulating film containing a spin-on-glass film, in a tape carrier package.

The above described and another objects and novel characteristics of the present invention will be apparent by from the description in this specification and accompanying drawings.

Among the features disclosed by this application, representative ones will be summarized below.

(1) In a semiconductor integrated circuit device according to the present invention, an interlayer insulating film comprising at least a stacked layer composed of a first silicon oxide film, a spin-on-glass (SOG) film, and a second silicon oxide film is formed on a principal surface of a semiconductor chip; a bonding pad is formed on the interlayer insulating film; a plurality of interconnections (wiring lines) are disposed below the bonding pad at a predetermined pitch through the interlayer insulating film; and at least a portion of the spin-on-glass film on each of the plurality of interconnections has been removed. In other words the first silicon oxide film is formed to be in contact with the second silicon oxide film on the interconnections.

(2) In the semiconductor integrated circuit device according to the present invention, the plurality of interconnections are arranged in a pattern wherein they are extending in parallel to each other.

(3) In the semiconductor integrated circuit device according to the present invention, the plurality of interconnections are arranged in a pattern separated from each other as an island.

(4) In the semiconductor integrated circuit device according to the present invention, the plurality of interconnections are dummy ones in an electrically floating state.

(5) In the semiconductor integrated circuit device according to the present invention, a second interconnection is disposed below the plurality of interconnections through a second interlayer insulating film.

(6) In the semiconductor integrated circuit device according to the present invention, the bonding pad is formed in a first region and in this first region, the spin-on-glass film is embedded in a space between two contiguous interconnections of the plurality of interconnections. In a second region, a semiconductor device is formed. In the second region, second interconnections similar to the interconnections are formed, and between two contiguous interconnections of the second interconnection the spin-on-glass film is embedded and the portion of the spin-on-glass film over each of the second interconnections has been removed.

(7) In the semiconductor integrated circuit device according to the present invention, a memory cell of a DRAM comprising a MISFET for the selection of a memory cell and a capacitor for the information storage disposed thereon is formed in a first region on a principal surface of the semiconductor chip; an interlayer insulating film comprising at least a stacked layer composed of a first silicon oxide film, a spin-on-glass film, and a second silicon oxide film is formed over the capacitor for the information storage; a bonding pad is formed on the interlayer insulating film in a second region on the principal surface of the semiconductor chip; a plurality of interconnections are disposed below the bonding pad through the interlayer insulating film at a predetermined pitch; and at least a portion of the spin-on-glass film over each of the plurality of interconnections has been removed.

(8) The semiconductor integrated circuit device according to the present invention is a tape carrier package having one end portion of a lead bonded onto the bonding pad of the semiconductor chip through a bump electrode.

(9) The process for fabricating a semiconductor integrated circuit device according to the present invention comprise the steps of:

(a) Forming a semiconductor device in a first region on a principal surface of a semiconductor chip,

(b) Forming one or more interconnection layers over the semiconductor device through at least one interlayer insulating film,

(c) Forming an uppermost interconnection layer of one or more of the interconnection layers and disposing a plurality of interconnections in a second region on the principal surface of the semiconductor chip at a predetermined pitch,

(d) Depositing a first silicon oxide film over-the uppermost interconnection layer including the plurality of interconnection layers and then applying a spin-on-glass film over the first silicon oxide film,

(e) Removing at least a portion of the spin-on-glass film over each of the plurality of interconnections in the first and second regions by etch back of the spin-on-glass film, and

(f) Depositing a second silicon oxide film on the principal surface of the semiconductor chip and then forming a bonding pad over the plurality of interconnection layers by patterning an electro-conductive layer deposited over the second silicon oxide film in the second region. The first silicon oxide film is brought into contact with the second silicon oxide film at the position over the plurality of interconnections.

(10) In the process for fabricating a semiconductor integrated circuit device according to the present invention, the plurality of interconnections are disposed in a pattern extending in parallel to each other.

(11) In the process for fabricating a semiconductor integrated circuit device according to the present invention, the plurality of interconnections are disposed in a pattern separated from each other as an island.

(12) In the process for fabricating a semiconductor integrated circuit device according to the present invention, the plurality of interconnections form dummy ones under an electrically floating state.

(13) In the process for fabricating a semiconductor integrated circuit device according to the present invention, one or more interconnection layers is formed below the bonding pad in the step (b).

(14) The process for fabricating a semiconductor integrated circuit device according to the present invention comprises the steps of:

(a) depositing a first electro-conductive layer on a principal surface of a semiconductor chip, forming a gate electrode of a MISFET for the selection of a memory cell which constitutes a portion of a memory cell of a DRAM in a first region on the principal surface of the semiconductor chip by patterning the first electro-conductive layer, and forming a gate electrode of a MISFET which constitutes a peripheral circuit of the DRAM in a second region on the principal surface of the semiconductor chip;

(b) depositing a second electro-conductive layer over the MISFET for the selection of a memory cell and, the MISFET of the peripheral circuit through a first insulating film and then forming a bit line connected with either one of a source region or drain region of the MISFET for the selection of a memory cell and a first interconnection layer of the peripheral circuit connected with-either one of a source region or a drain region of the MISFET of the peripheral circuit by patterning the second electro-conductive layer,

(c) depositing a third electro-conductive layer over the bit line and the first interconnection layer through a second insulating film and then patterning the third electro-conductive layer to form a lower electrode for a capacitor for information storage which is connected with the other one of the source region or drain region of MISFET for the selection of a memory cell.

(d) depositing a fourth electro-conductive layer over the lower electrode for a capacitor for information storage through a third insulating film and forming an upper electrode and a capacitive insulating film for the capacitor for information storage by patterning the fourth electro-conductive layer and third insulating film;

(e) depositing a fifth electro-conductive layer over the capacitor for information storage through a fourth insulating film and then forming an interconnection connected with the upper electrode for the capacitor for information storage and a second interconnection layer of peripheral circuit by patterning the fifth electro-conductive layer;

(f) disposing a plurality of interconnections in a third region on the principal surface of the semiconductor chip at a predetermined pitch by patterning the fifth electro-conductive layer in the step (e);

(g) depositing a first silicon oxide film over the interconnection connected with the upper electrode of the capacitor for information storage, the second interconnection layer of the peripheral circuit and the plurality of interconnections and then applying a spin-on-glass film on the first silicon oxide film;

(h) removing at least a portion of the spin-on-glass film on the plurality of interconnections by the etch back of the spin-on-glass film; and

(i) depositing a second silicon oxide film on the principal surface of the semiconductor chip and patterning a sixth electro-conductive layer deposited over the second silicon oxide film, thereby forming a bonding pad over the plurality of interconnections.

(15) In the process for fabricating a semiconductor integrated circuit device according to the present invention, at least one electro-conductive layer of the first to fourth electro-conductive layers is patterned and one or more interconnection layers is formed below the bonding pad.

(16) The process for fabricating a tape carrier package according to the present invention comprises the steps of:

(a) preparing a semiconductor chip and an insulating tape having a lead formed on at least one side thereof, the semiconductor chip having an interlayer insulating film—which contains at least a stacked layer composed of a first silicon oxide film, a spin-on-glass film and a second silicon oxide film—formed on the principal surface of the semiconductor chip; having a bonding formed over the interlayer insulating film; having plural interconnections disposed at a predetermined pitch through the interlayer insulating film; and having at least a portion of the spin-on-glass film over each of the plurality of interconnections removed;

(b) wire bonding a metal ball onto the bonding pad of the semiconductor chip;

(c) flattening the surface of the metal ball, thereby forming a bump electrode on the bonding pad; and

(d) bonding one end portion of the lead formed on the insulating tape onto the bump electrode.

(17) A multi-chip module according to the present invention is obtained by stacking a plurality of the tape carrier packages and mounting it on a printed circuit board.

(18) The semiconductor integrated circuit device according to the present invention comprises an interlayer insulating film, which contains at least a stacked layer composed of a first insulating film, a flattened film, and a second insulating film, formed on the principal surface of a semiconductor chip and a bonding pad formed over the interlayer insulating film, and in it, a plurality of interconnections have been disposed below the bonding pad through the interlayer insulating film; the first insulating film and the second insulating film are formed to be brought into contact on at least the plurality of interconnections; and the adhesion between the first insulating film and second insulating film is larger than that between the first or second insulating film and the flattened film.

(19) In the semiconductor integrated circuit device according to the present invention, the first insulating film and second insulating film are formed of the same insulating material.

### BRIEF DESCRIPTION OF THE DRAWINGS

FIG. 1 is an overall plan view illustrating a semiconductor chip having a DRAM formed thereon according to an embodiment of the present invention.

FIG. 2 is an enlarged plan view illustrating a semiconductor chip having a DRAM formed thereon according to t-he embodiment of the present invention.

FIG. 3 is a fragmentary cross-sectional view illustrating a semiconductor chip having a DRAM formed thereon according to the embodiment of the present invention.

FIG. 4 is another fragmentary cross-sectional view illustrating a semiconductor chip having a DRAM formed thereon according to the embodiment of the present invention.

FIG. 5 is a plan view illustrating a bonding pad and interconnection (dummy interconnection) patterns disposed therebelow.

FIG. 6 is a fragmentary cross-sectional view of a semiconductor substrate illustrating a step of a fabrication process of a DRAM according to the embodiment of the present invention.

FIG. 7 is a fragmentary cross-sectional view of a semiconductor substrate illustrating a step of a fabrication process of a DRAM according to the embodiment of the present invention.

FIG. 8 is a fragmentary cross-sectional view of a semiconductor substrate illustrating a step of a fabrication process of a DRAM according to the embodiment of the present invention.

FIG. 9 is a fragmentary cross-sectional view of a semiconductor substrate illustrating a step of a fabrication process of a DRAM according to the embodiment of the present invention.

FIG. 10 is a fragmentary cross-sectional view of a semiconductor substrate illustrating a step of a fabrication process of a DRAM according to the embodiment of the present invention.

FIG. 11 is a fragmentary cross-sectional view of a semiconductor substrate illustrating a step of fabrication process of a DRAM according to the embodiment of the present invention.

FIG. 12 is a fragmentary cross-sectional view of a semiconductor substrate illustrating a step of a fabrication process of a DRAM according to the embodiment of the present invention.

FIG. 13 is a fragmentary cross-sectional view of a semiconductor substrate illustrating a step of a fabrication process of a DRAM according to the embodiment of the present invention.

FIG. 14 is a fragmentary cross-sectional view of a semiconductor substrate illustrating a step of a fabrication process of a DRAM according to the embodiment of the present invention.

FIG. 15 is a fragmentary cross-sectional view of a semiconductor substrate illustrating a step of a fabrication process of a DRAM according to the embodiment of the present invention.

FIG. 16 is a fragmentary cross-sectional view of a semiconductor substrate illustrating a step of a fabrication process of a DRAM according to the embodiment of the present invention.

FIG. 17 is a fragmentary cross-sectional view of a semiconductor substrate illustrating a step of a fabrication process of a DRAM according to the embodiment of the present invention.

FIG. 18 is a fragmentary cross-sectional view of a semiconductor substrate illustrating a step of a fabrication process of a DRAM according to the embodiment of the present invention.

FIG. 19 is a fragmentary cross-sectional view of a semiconductor substrate illustrating a step of a fabrication process of a DRAM according to the embodiment of the present invention.

FIG. 20 is a fragmentary cross-sectional view of a semiconductor substrate illustrating a step of a fabrication process of a DRAM according to the embodiment of the present invention.

FIG. 21 is a fragmentary cross-sectional view of a semiconductor substrate illustrating a step of a fabrication process of a DRAM according to the embodiment of the present invention.

FIG. 22 is a fragmentary cross-sectional view of a semiconductor substrate illustrating a step of a fabrication processor a DRAM according to the embodiment of the present invention.

FIG. 23 is a fragmentary cross-sectional view of a semiconductor substrate illustrating a step of a fabrication process of a DRAM according to the embodiment of the present invention.

FIG. 24 is a fragmentary cross-sectional view of a semiconductor substrate illustrating a step of a fabrication process of a DRAM according to the embodiment of the present invention.

FIG. 25 is a fragmentary cross-sectional view of a semiconductor substrate illustrating a fabrication step of a process of a DRAM according to the embodiment of the present invention.

FIG. 26 is a fragmentary cross-sectional view of a semiconductor substrate illustrating a step of a fabrication process of a DRAM according to the embodiment of the present invention.

FIG. 27 is a schematic view illustrating the width and space of interconnections (dummy interconnections) disposed below the bonding pad.

FIG. 28 is a fragmentary cross-sectional view of a semiconductor substrate illustrating a step of a fabrication process of a DRAM according to the embodiment of the present invention.

FIG. 29 is a fragmentary cross-sectional view of a semiconductor substrate illustrating a step of a fabrication process of a DRAM according to the embodiment of the present invention.

FIG. 30 is a perspective view illustrating a fabrication process of TCP according to the embodiment of the present invention.

FIG. 31 is a fragmentary cross-sectional view illustrating a step of a fabrication process of TOP according to the embodiment of the present invention.

FIG. 32 is a fragmentary cross-sectional view illustrating a step of a fabrication process of TCP according to the embodiment of the present invention.

FIG. 33 is a fragmentary cross-sectional view illustrating a step of a fabrication process of TCP according to the embodiment of the present invention.

FIG. 34 is a fragmentary plan view illustrating a step of a fabrication process of TOP according to the embodiment of the present invention.

FIGS. 35(a) and (b) are each a fragmentary plan view illustrating a fabrication process of TCP according to the embodiment of the present invention.

FIG. 36 is a perspective view illustrating a fabrication process of TOP according to the embodiment of the present invention.

FIG. 37 is a fragmentary cross-sectional view illustrating a fabrication process of TOP according to the embodiment of the present invention.

FIG. 38 is a fragmentary cross-sectional view illustrating a stacked memory module according to the embodiment of the present invention.

FIGS. 39(a) and (b) are each a fragmentary plan view illustrating a fabrication process of TCP according to another embodiment of the present invention.

FIG. 40 is a plan view illustrating a bonding pad and interconnections (dummy interconnections) disposed therebelow according to another embodiment of the present invention.

FIG. 41 is a fragmentary cross-sectional view of a semiconductor substrate illustrating a fabrication process of a DRAM according to another embodiment of the present invention.

FIGS. 42(a), (b), and (c) are each a fragmentary schematic view illustrating a peeling mode of a bonding pad studied by the present inventor.

FIGS. 43(a), (b), and (c) are each a fragmentary schematic view illustrating a fabrication flow of TCP by the post-step bump method.

FIG. 44 is a plan view illustrating a bonding pad and a pattern of interconnections (dummy interconnections) disposed therebelow according to another embodiment of the present invention.

FIG. 45 is a fragmentary cross-sectional view of a semiconductor chip having a DRAM formed thereon according to another embodiment of the present invention.

FIG. 46 is a fragmentary cross-sectional view of a semiconductor chip having a DRAM formed thereon according to another embodiment of the present invention.

### DETAILED DESCRIPTION OF THE PREFERRED EMBODIMENTS

An embodiment of the present invention will be described more specifically based on the accompanying drawings. In all the drawings for the description of the various embodiments, like elements of function will be identified by like reference numerals and overlapping descriptions will be omitted.

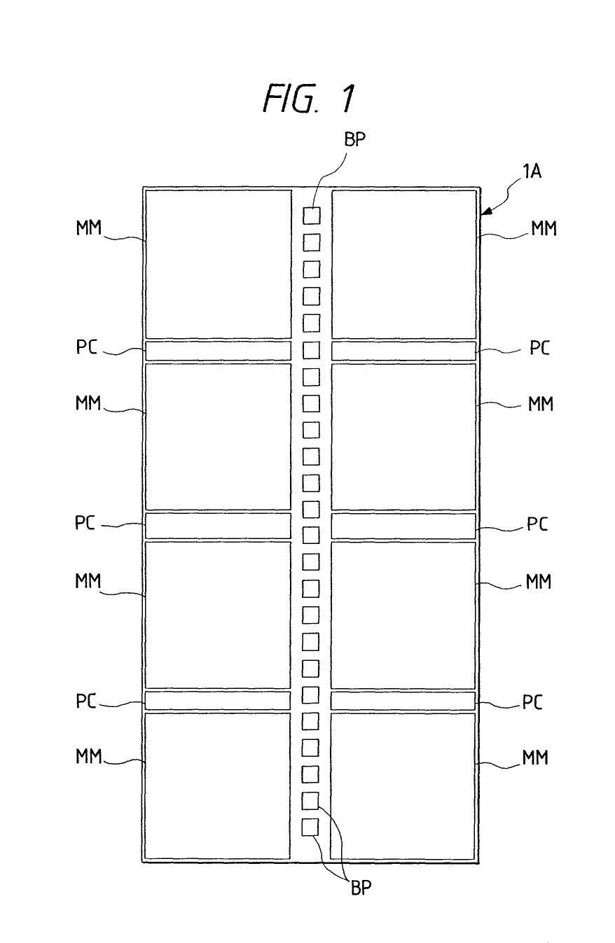

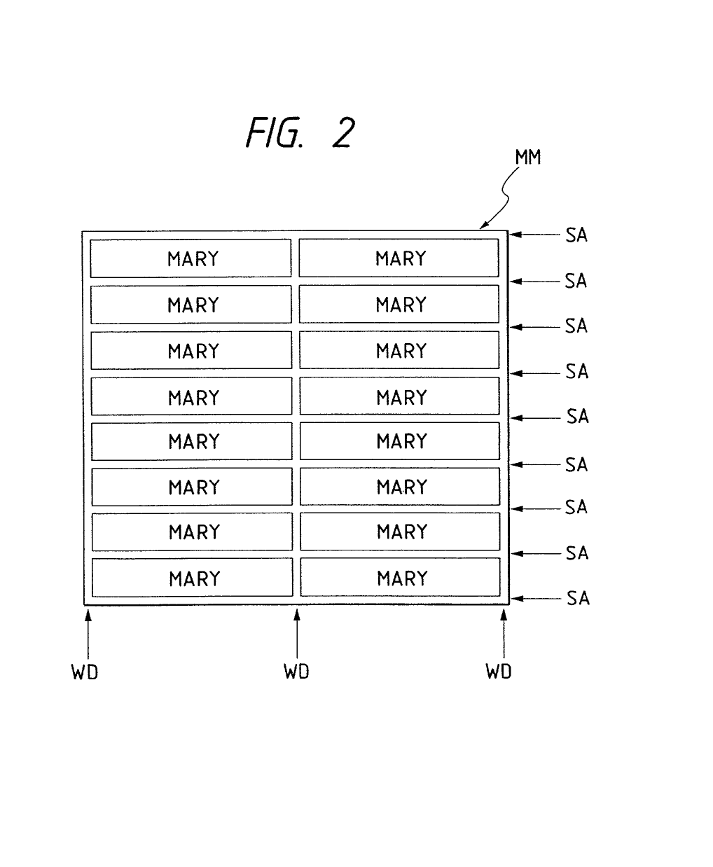

FIG. 1 is an overall plan view of a semiconductor chip having a DRAM formed thereon according to the an embodiment of the present invention; and FIG. 2 is an enlarged plan view illustrating a portion of FIG. 1.

On a principal surface composed of single crystal silicon, a DRAM having, for example, a capacity of 64 Mbits (mega-bits) has been formed. As illustrated in FIG. 1, this DRAM is formed of a memory mat MM divided into 8 pieces and peripheral circuits disposed at the peripheries of the divided memory mat pieces. Each piece of the memory mat MM having a capacity of 8 Mbits is divided into 16 memory arrays MARY as illustrated in FIG. 2. Each of the memory arrays MARY is formed of memory cells of 512 Kbits (2 Kbits (kilobits)×256 bits) which have been arranged in a line and at the peripheries thereof, peripheral circuits (PC), such as sense amplifier SA or word driver WD, have been arranged. At the center of a semiconductor chip 1A, sandwiched by memory mats MM, a plurality of bonding pads BP, to be connected with an external connecting terminal (lead) of an LSI package to have the semiconductor chip 1A sealed therein, are arranged in a row.

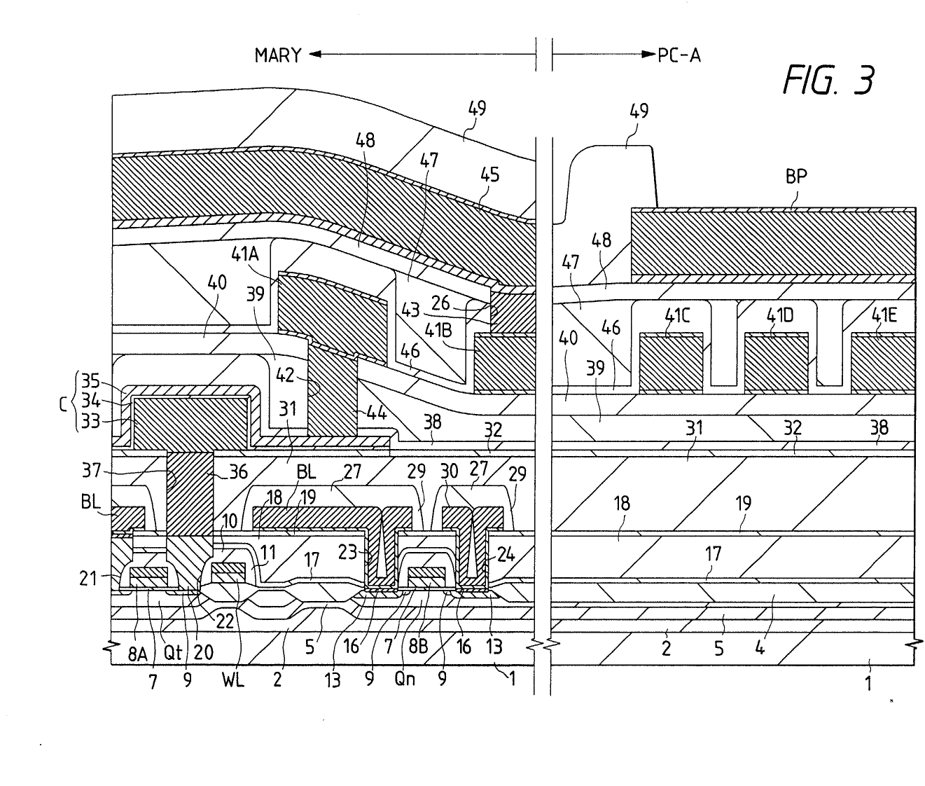

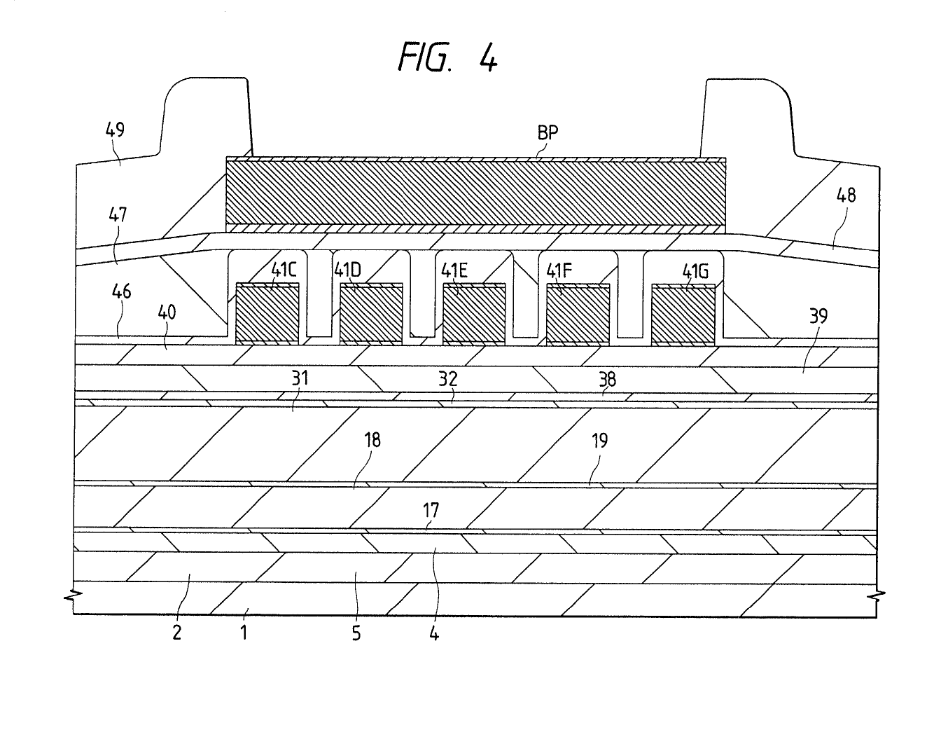

FIGS. 3 and 4 are fragmentary cross-sectional views of the above-described semiconductor chip 1A having a DRAM formed thereon. The left-side of FIG. 3 illustrates a part of a memory array (MARY) and a peripheral circuit (PC) contiguous thereto, while the right sides (a memory array formation region MARY) of FIG. 3 and FIG. 4 illustrate a region for the formation of a bonding pad (BP).

For example, on a semiconductor substrate 1 composed of p⁻-type single crystal silicon, a p-type well 2 common to the memory array (MARY) and the peripheral circuit (PC) is formed—on the surface of the p-type well 2, a field oxide layer 4 for element isolation is formed and inside of the p-type well 2, including the lower part of the field oxide layer 4, a p-type channel stopper layer 5 is formed.

In an active region of the p-type well 2 of the memory array (MARY), memory cells for a DRAM, as a semiconductor element, are formed. Each of the memory cells is formed of one n-channel type MISFETQt for the selection of a memory cell and one capacitor C for information storage connected in series with the MISFETQt for the selection of a memory cell. In other words the memory cell has a stacked capacitor structure having capacitor C for information storage disposed over the MISFETQt for the selection of a memory cell.

The MISFETQt for the selection of a memory cell is formed of a gate oxide film 7, a gate electrode 8A formed integrally with a word line WL, a source region and a drain region (h-type semiconductor regions 9, 9), and a channel region (not illustrated) having a p-type well 2 formed between the source region and drain region. The gate electrode 8A (word line WL) is formed of an electroconductive layer composed of two stacked layers, that is, a low-resistance polycrystalline silicon film having n-type impurities (for example, P (phosphorus)) doped thereinto and a tungsten silicide (WSi2) film; or an electro-conductive layer composed of three stacked layers, that is, a low-resistance polycrystalline silicon film, a TiN (titanium nitride) film and a W (tungsten) film. Above the gate electrode 8A (word line WL), a silicon nitride film 10 is formed and on each of the side walls of it, a side wall spacer 11 composed of silicon nitride is formed. These insulating films (silicon nitride film 10 and side wall spacer 11) can be formed of silicon oxide instead of a silicon nitride.

In an active region of the p-type well 2 of the peripheral circuit (PC), an n-channel type MISFETQn is formed, while in a region not illustrated, a p-channel type MISFET is formed. In other word the peripheral circuit (PC) is formed of a CMOS (complementary metal oxide semiconductor) circuit having an n-channel type MISFETQn and a p-channel type MISFET in combination.

The n-channel type MISFETQn of the peripheral circuit (PC), as a semiconductor element, is formed of a gate oxide film 7, gate electrode 8B, a source region and a drain region, and a channel region (not illustrated) disposed between the source and drain regions and having a p-type well 2 formed therein. The gate electrode 8B is formed of an electro-conductive layer similar to that for the gate electrode 8A (word line WL) of the MISFETQt for the selection of a memory cell. Above the gate electrode 8B, a silicon nitride film 10 is formed and on each of the side walls of it, a side wall spacer 11 made of silicon nitride is formed. Each of the source region and drain region of the n -channel type MISFETQn has an LDD (lightly doped drain) structure composed of an n-type semiconductor region 9 having a low impurity concentration and an n⁺-type semiconductor region 13 having a high impurity concentration. On the surface of the n⁺-type semiconductor region 13, a titanium silicide (TiSi2) film 16 is formed.

Over the MISFETQt for the selection of a memory cell and n-channel type MISFETQn, a silicon oxide film 17, BPSG (boron-doped phospho silicate glass) film 18, and a silicon oxide film 19 are stacked one after another in this order.

Over the silicon oxide film 19 of a memory array (MARY) a bit line BL composed of two electro-conductive layers, that is, a TiN film and a W film stacked one after another is formed. The bit line BL is electrically connected with one of the source region and drain region of MISFETQt for the selection of a memory cell through a connecting hole 21 having a phosphorus (P) or arsenic (AS)-doped polycrystalline silicon plug 20 buried therein. one end portion of the bit line BL is electrically connected with one of the source region and drain region (n⁺-type semiconductor region 13) of the n-channel type MISFETQn of the peripheral circuit (PC) through a connecting hole 23. On the surface of the n⁺-type semiconductor region 13, a low-resistance Ti silicide film 16 is formed so that a contact resistance of the bit line BL can be reduced.

Over the silicon oxide film 19 of the peripheral circuit (PC), a first interconnection layer 30 is formed. The interconnection layer 30, similar to the above-described bit line BL, is composed of two electro-conductive layers, that is, TiN film and W film stacked one after another one end of the interconnection layer 30 is electrically connected with the other one of the source region and drain region (n⁺-type semiconductor region 13) of the n-channel type MISFETQn thorough a connecting hole 24. On the surface of the n⁺-type semiconductor region 13, a low-resistance Ti silicide film 16 is formed so that the contact resistance of the interconnection 30 can be reduced.

Over the bit line BL and the first interconnection layer 30, a silicon nitride film 27 is formed and on each of the side walls, a side wall spacer 29 made of silicon nitride is formed. Above the bit line BL and the Interconnection 30, an SOG film 31 and a silicon oxide film 32 are formed. Over the silicon oxide film 32 of the memory array (MARY), a capacitor C for information storage composed of an accumulation electrode (lower electrode) 33, a capacitive insulating film 34 and a plate electrode (upper electrode) 35 is formed.

The accumulation electrode 33 for the capacitor C for the information storage is formed of a W film and is electrically connected with the other one of the source region and drain region (n-type semiconductor region 9) of MISFETQt for the selection of a memory cell through a connecting hole 37 having a W (or polycrystalline silicon) plug 36 embedded therein and a connecting hole 22 having a polycrystalline silicon plug 20 embedded therein. The capacitive insulating film 34 is formed of a Ta₂O₅ (tantalum oxide) film, while the plate electrode 35 is formed of a TiN film.

On the capacitor C for information storage, an interlayer insulating film, composed of three films, that is, a silicon oxide film 38, an SOG film 39, and a silicon oxide film 40, is formed. on the interlayer insulating film, an interconnection (wiring line) 41A for supplying the plate electrode (upper electrode) of the capacitor C for information storage with a plate voltage (Vdd/2) and a second interconnection layer (wiring line) 41B of the peripheral circuit (PC) are formed. The interconnection 41A is electrically connected with the plate electrode 35 through a connecting hole 42 opened in the intrastratum insulating layer (silicon oxide film 40, SOG film 39, and silicon oxide film 38) on the plate electrode 35 of the capacitor for the information storage. The connecting hole 42 has a W-made plug 44 embedded inside thereof.

On the interlayer insulating film (silicon oxide film 40, SOG film 39, and silicon oxide film 38) in a region for the formation of a pad, interconnections (dummy interconnections) 41C to 41G each of which is substantially free from a function as an interconnection and is under an electrically floating state are disposed closely at a predetermined pitch. The interconnections 41A and 41B and interconnections (dummy interconnections) 41C to 41G each have three films, that is, a TiN film, an Al (aluminum) alloy layer to which Si (silicon) and Cu (copper) have been added and a TiN film, the three films being stacked one after another in the order of mention.

On the interconnections 41A to 41G, a bonding pad BP and a third interconnection layer 45 are formed through an interlayer insulating film formed of three films, that is, a silicon oxide film 46, an SOG film 47, and a silicon oxide film 48. The interconnection film 45 is electrically connected with the second interconnection layer 41B through a connecting hole 26 formed in the interlayer, insulating film (silicon oxide film 46, SOG film 47, and silicon oxide film 48) The connecting hole 26 has a W-made plug 43 embedded inside thereof. The bonding pad BP and the interconnection 45 are each composed of three films, for example, a W film, an Al alloy film, and a W film which have been stacked one after another.

On the surface of the semiconductor chip 1A, except for the upper portion of the bonding pad BP, a passivation film 49 is formed. The passivation film 49 is formed of two films, for example, a silicon oxide film and a silicon nitride film.

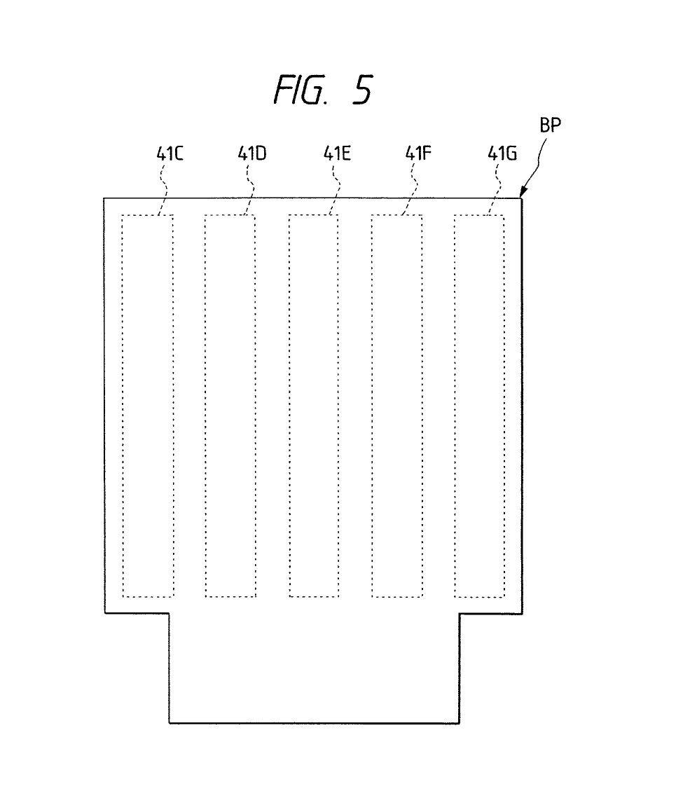

FIG. 5 is a plan view of the above-described bonding pad BP. The bonding pad BP has a square plane pattern about 100 pm long×100 pm broad, on which one end portion of a lead is to be bonded in the fabrication step of the TCP (tape carrier package) which will be described later.

Below the bonding pad BP, the above-described interconnections (dummy interconnections) 41C to 41G are arranged in the form of a stripe at a predetermined pitch. As illustrated in FIG. 4, an interlayer insulating film, composed of three films, that is, a silicon oxide film 46, an SOG film 47, and a silicon oxide film 48, is formed between the bonding pad BP and the interconnections 41C to 41G therebelow. The SOG film 47 which is an intermediate layer of the interlayer insulating film is formed only in the narrow space between two contiguous interconnections of the closely arranged interconnections (wiring lines) 41C to 41G and is not formed on the interconnections 41C to 41G. In other words, most of the interlayer insulating film below the bonding pad BP is formed of two films, that is the silicon oxide film 46 and silicon oxide film 48, and the existence of the interlayer insulating film composed of three films is only limited in the narrow space between two contiguous interconnections of the interconnections 41C to 41G.

As described above, the DRAM according to the embodiment of the present invention has an interlayer insulating film formed of three films, that is the silicon oxide film 46, SOG film 47, and silicon oxide film 48 which is excellent in flatness, which makes it possible to reduce a step difference between the memory array (MARY) and the peripheral circuit (PC). In the interlayer insulating film below the bonding pad BP, the adhesion of the component layers is heightened by decreasing the area occupied by the SOG film 47 which has comparatively low adhesion with the silicon oxide films 46 and 48 by increasing a direct contact area of the silicon oxide films 46 and 48, which are made of the same material above the interconnections 41C to 41G. In other words, since the adhesion between the silicon oxide film 46 and silicon oxide film 48 is larger than that between the silicon oxide film 46 and SOG film 47 or between the silicon oxide film 48 and SOG film 47 among three insulating films (silicon oxide film 46, SOG film 47, and silicon oxide film 48) constituting the interlayer insulating film, the interconnections 41C to 41G are arranged so that the direct contact area of the silicon oxide films 46 and 48 increases. Incidentally, it is not necessary to use the same material for the two insulating films having the SOG film 47 therebetween and any material can be used insofar as it permits larger adhesion of these two upper and lower films than the adhesion with the intermediate SOG film 47.

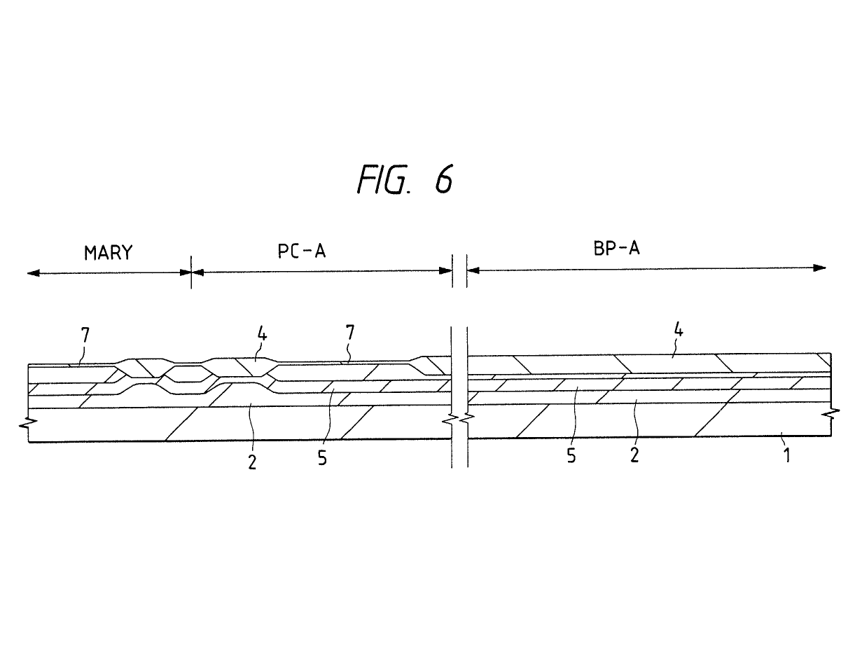

A process for the fabrication of the DRAM according to the present invention will next be described in detail with reference to FIGS. 6 to 29.

As illustrated in FIG. 6, after a field oxide film 4 is formed on the surface of a p⁻-type semiconductor substrate 1 having a specific resistance of about 1 to 10 Ωcm by the local oxidation method of silicon (LOCOS), p-type impurities (boron (B)) are ion-implanted to a region for the formation of a memory cell (MARY) and a region (PC-A) for the formation of an n-channel type MISFET of the peripheral circuit (PC) on the semiconductor substrate 1, whereby a p-type well 2 is formed. Then, p-type impurities (B) are ion-implanted to the p-type well 2 to form a p-type channel stopper layer 5 is formed. Incidentally, an n-type well is formed in a not illustrated region of the semiconductor substrate 1. In it a p-channel type MISFET constituting a portion of the peripheral circuit (PC) is formed, but the description of the fabrication process is omitted.

On the surface of an active region of the p-type well 2 surrounded by the field oxide layer 4, a gate oxide film 7 is formed by the thermal oxidation method, followed by ion implantation of impurities into the p-type well 2 through the gate oxide film 7 in order to control the threshold voltage (Vth) of the MISFET. It is possible to carry out the ion implantation for the formation of the p-type well 2, ion plantation for the formation of the p-type channel stopper layer 5, and ion implantation for the control of the threshold voltage (Vth) of the MISFET in the same step by using the same photoresist mask. Alternatively, it is also possible to carry out ion implantation for the control of the threshold voltage (Vth) of MISFETQt for the selection of a memory cell and ion implantation for the control of the threshold voltage (Vth) of the n-channel type MISFETQn of the peripheral circuit (PC) in respective steps and to control the threshold voltage (Vth) independently in each MISFET.

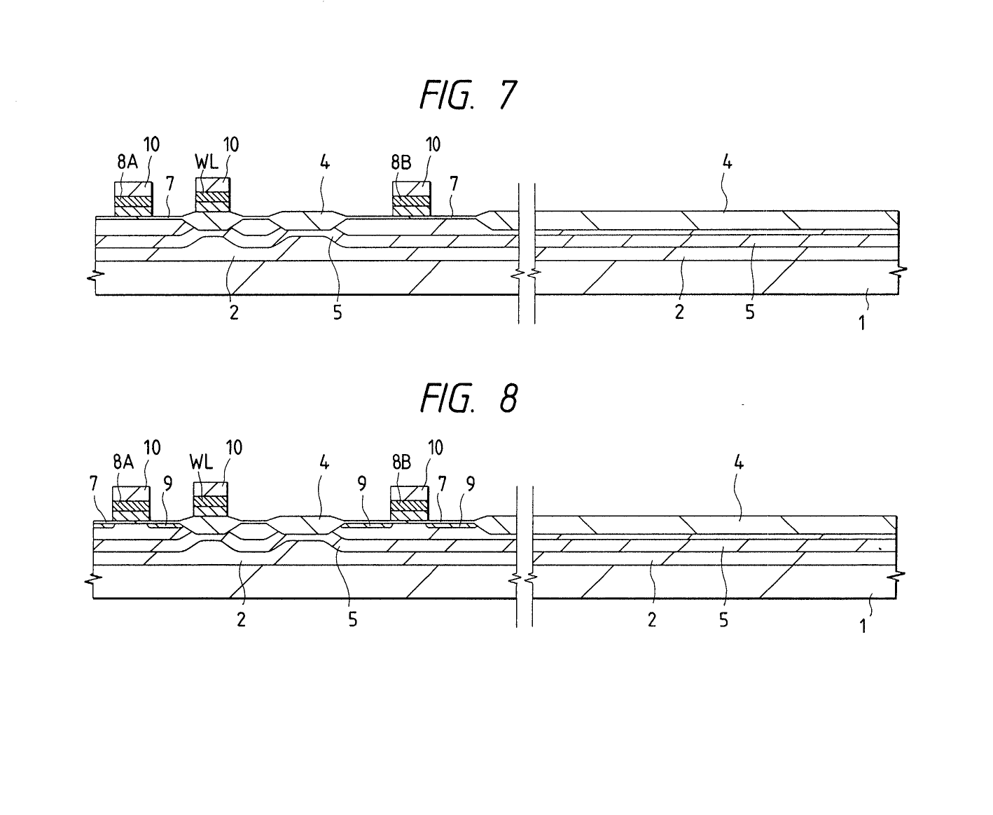

As illustrated in FIG. 7, a gate electrode 8A (word line WL) of MISFETQt for the selection of a memory cell and a gate electrode 8B of the n-channel type MISFETQn are formed. The gate electrode 8A (word line WL) and gate electrode 8B are formed simultaneously, for example, by depositing on the semiconductor substrate 1 an n-type polycrystalline silicon film, a WSi2 film and a silicon nitride film 10 successively by the CVD method and then patterning these films by etching with a photoresist as a mask. Alternatively, the gate electrode 8A and gate electrode 8B are formed simultaneously by depositing an n-type polycrystalline layer by the CVD method, depositing a TiN film and a W film by the sputtering method, depositing a silicon nitride film 10 by the CVD method and then patterning these films by etching with a photoresist as a mask. The TiN film is used as a barrier metal for preventing the reaction between the polycrystalline silicon film and the W film. The sheet resistance of the gate electrode 8A (word line WL) and the gate electrode 8B can be reduced furthermore by employing a material of a lower resistance such as an electro-conductive layer composed of three films, for example, a TiN film (or WN (tungsten nitride) film) and Ti silicide film, the three films being stacked one after another on an n-type polycrystalline silicon film.

As illustrated in FIG. 8, n-type impurities (P) are ion-implanted into the p-type well 2, whereby an n-type semiconductor region 9 of MISFETQt for the selection of a memory cell and an n-type semiconductor region 9 of an n-channel type MISFETQn are formed by self alignment for the gate electrodes 8A, 8A. At this time, it is also possible to carry out ion plantation for the formation of the n-type semiconductor region 9 of MISFETQt for the selection of a memory cell and ion implantation for the formation of an n-type semiconductor region 9 of the n-channel-type MISFETQn in respective steps and control the impurity concentrations of the source region and drain regions independently in each MISFET.

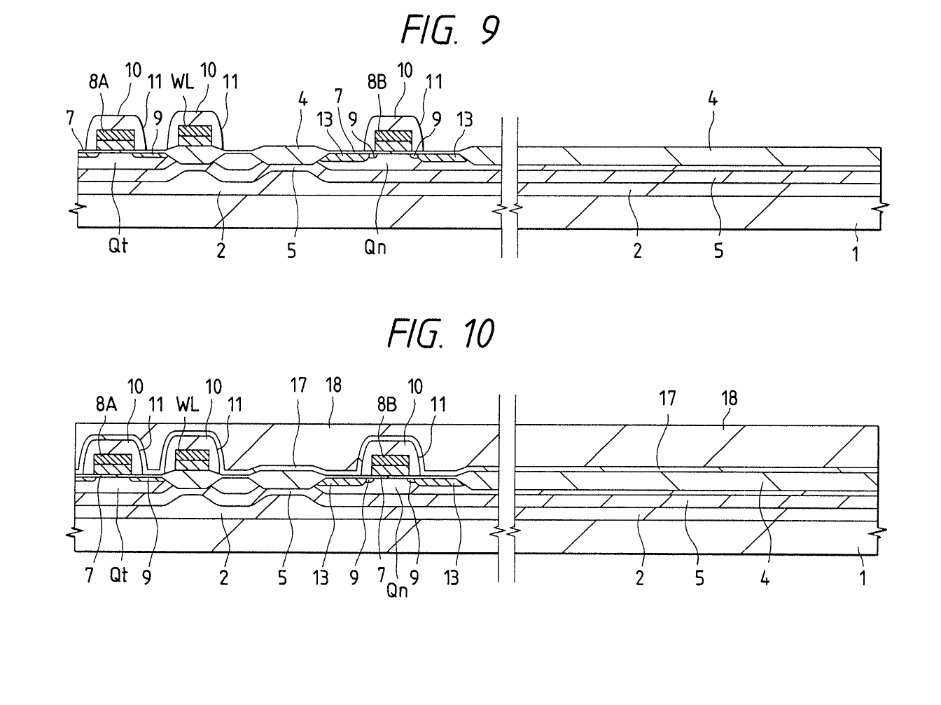

As illustrated in FIG. 9, a side wall spacer 11 is then formed on each side wall of the gate electrode 8A (word line WL) of MISFETQt for the selection of a memory cell and the gate electrode 8B of the n-channel type MISFETQn. The side wall spacer 11 is formed by anisotropic etching of a silicon nitride layer deposited by the CVD method. Then, n-type impurities (P) are ion-implanted into the p-type well 2 of the peripheral circuit (PC), whereby an n⁺-type semiconductor region 13 of the n-channel type MISFETQn is formed by self alignment with the side wall spacer 11. It is also possible to form one or both of the source region and drain region of the n-channel type MISFETQn which constitute the peripheral circuit (PC) as a single drain structure or as a double diffused drain structure.

As illustrated in FIG. 10, after a silicon oxide film 17 and a BPSG film 18 are deposited above the gate electrode 8A (word line WL) of MISFETQt for the selection of a memory cell and the gate electrode 8B of the n-channel type—MISFETQn by the CVD method, the BPSG film 18 is polished by the chemical mechanical polishing (CMP) method, whereby the surface of the film is flattened.

As illustrated in FIG. 11, after a polycrystalline silicon film 28 is deposited on the BPSG film 18 by the CVD method, the polycrystalline silicon film 28 is etched with a photoresist as a mask. Then, with the polycrystalline silicon film 28 as a mask, the BPSG film 18, silicon oxide film 17, and gate oxide film 7 are etched, whereby a connecting hole 21 is formed on one of the source region and drain region (n-type semiconductor region 9) of MISFETQt for the selection of a memory cell and a connecting hole 22 is formed on the other region (n-type semiconductor region 9).

At this time, the silicon nitride film 10 formed on the late electrode 8A (word line WL) of MISFETQt for the selection of a memory cell and the side wall spacer 11 made of silicon nitride and formed on the side walls remain without being etched substantially, because they differ in an etching rate with the silicon oxide insulating films (BPSG film 18, silicon oxide film 17, and gate oxide layer 7). More specifically, the gas used for dry etching for the formation of the connecting holes 21 and 22 has a high etching rate for the silicon oxide film, but a low etching rate for the silicon nitride film, which makes it possible to decrease the size of a memory cell, because in the region contiguous to the n-type semiconductor region 9, the minute connecting holes 21 and 22 each having a diameter smaller than the above-described photoresist mask can be formed by self alignment with the side wall spacer 11.

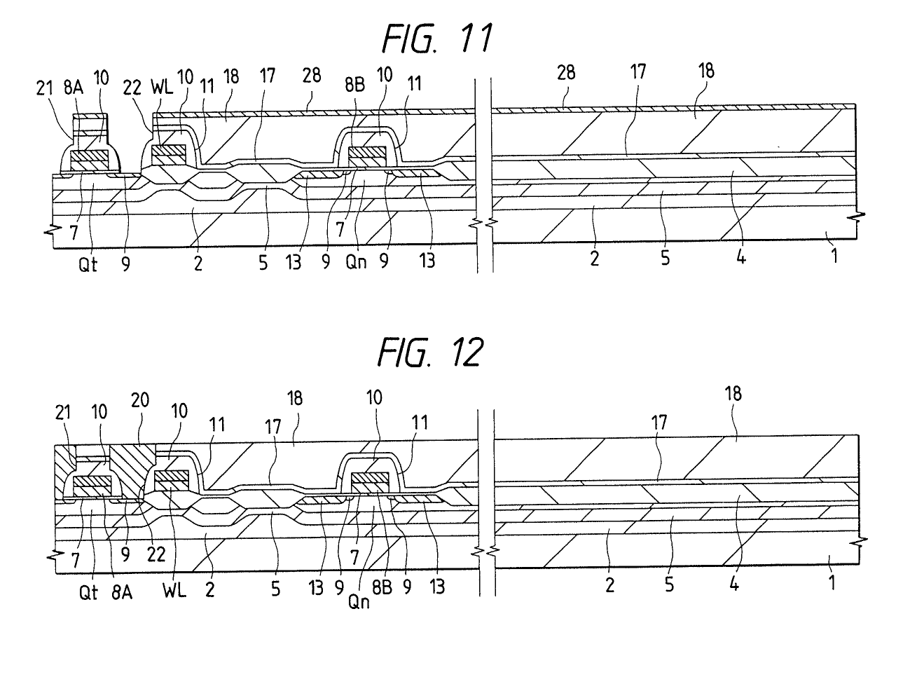

As illustrated in FIG. 12, a polycrystalline silicon plug 20 is embedded inside of each of the connecting holes 21 and 22. The plug 20 is formed by depositing a polycrystalline silicon film on the polycrystalline silicon film 28 by the CVD method and then removing the polycrystalline silicon film over the BPSG film 18 by etch back. At this time, the polycrystalline silicon film 28 used as the mask for etching is removed at the same time. Into the polycrystalline silicon film forming the plug 20, n-type impurities (P) are doped. Since the impurities diffuse into the n-type semiconductor region 9, 9 (source region, drain region) of MISFETQt for the selection of a memory cell through the connecting holes 21, 22, an n-type semiconductor region 9 having a higher impurity concentration than that of the n-type semiconductor region 9 of the n-channel type MISFETQn of the peripheral circuit (PC) is formed.

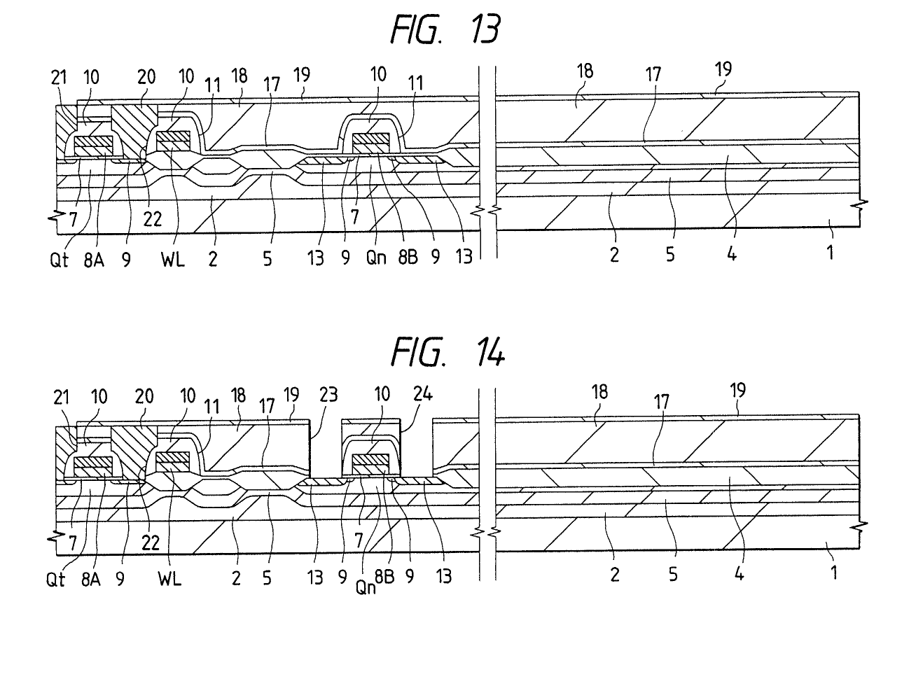

As illustrated in FIG. 13, after a silicon oxide film 19 is deposited over the BPSG film 18 by the CVD method, the silicon oxide film 19 over the connecting hole 21 is removed by etching with a photoresist as a mask to expose the plug 20. As illustrated in FIG. 14, the silicon oxide film 19, BPSG film 18, silicon oxide film 17, and gate oxide film 7 of the peripheral circuit (PC) are etched with a photoresist as a mask, whereby a connecting hole 23 is formed on-one of the source region and drain region (n⁺-type semiconductor region 13) of the n-channel type MISFETQn, while a connecting hole 24 is formed on the other region (n⁺-type semiconductor region 13).

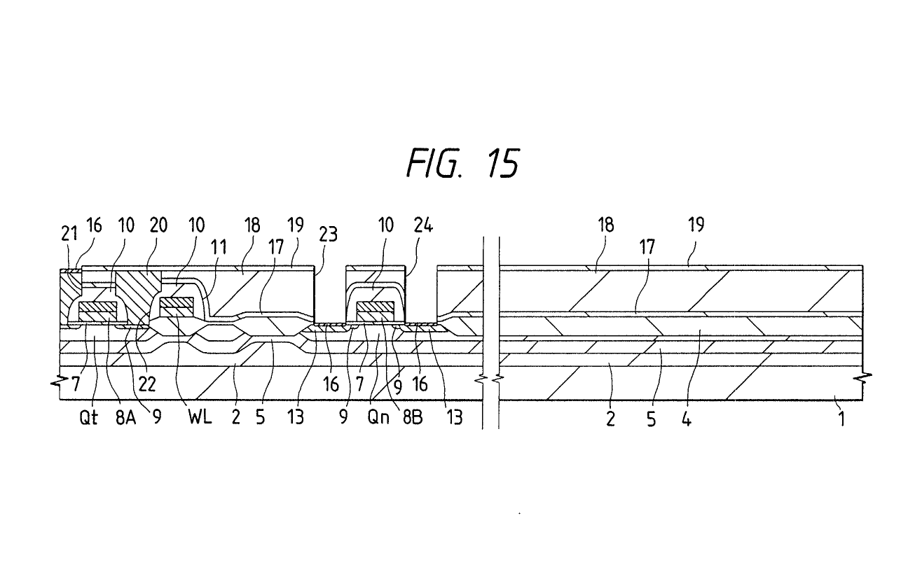

As illustrated in FIG. 15, a Ti silicide film 16 is formed on the surfaces of the n⁺-type semiconductor regions 13, 13 which are exposed at the bottoms of the connecting holes 23, 24 and also on the surface of the plug 20 to be connected with the bit line BL. The Ti silicide film 16 is formed by annealing a Ti film deposited by the sputtering method and then reacting it with an Si substrate (n⁺-type semiconductor region 13) and polycrystalline silicon (plug 20). Then, the unreacted portion of the Ti film remaining on the silicon oxide film 19 is removed by wet etching, whereby a Ti silicide film 16 is formed. The formation of the Ti silicide film 16 makes it possible to reduce a contact resistance between the source region, drain region and the plug 20 of the n-channel type MISFETQn and interconnections connected therewith (bit line BL, interconnection layer 30).

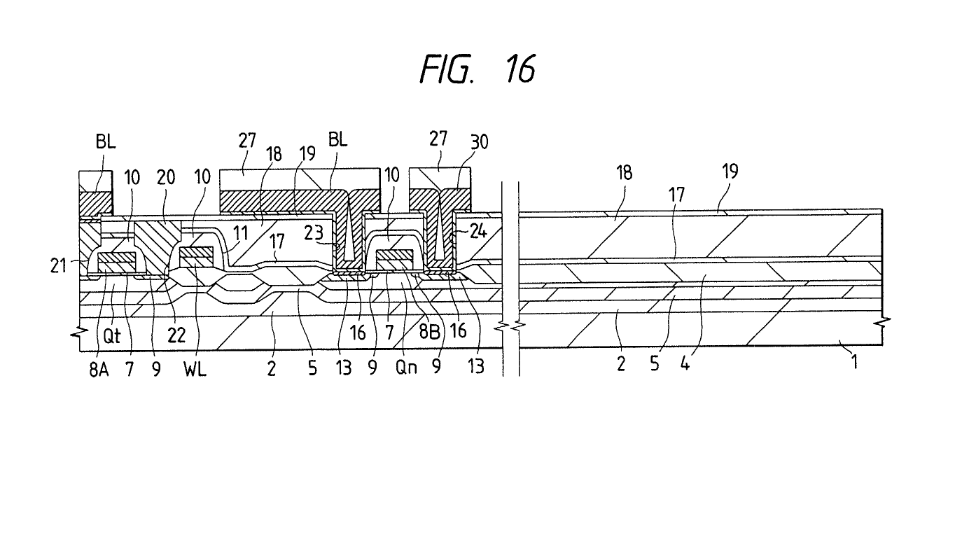

As illustrated in FIG. 16, a bit line BL is formed on the silicon oxide film 19 of a memory array (MARY), while a first interconnection layer 30 is formed on the silicon oxide film 19 of the peripheral circuit (PC) The bit line BL and the interconnection layer 30 are formed simultaneously by depositing a TiN film and a W film on the silicon oxide film 19 by the sputtering method, depositing thereon a silicon nitride film 27 by the CVD method, and then patterning these films by etching with a photoresist as a mask. It is also possible to form the bit line BL and the interconnection layer 30 by using a material of a lower resistance such as a two-layered electro-conductive layer having, for example, a TiN film (or WN film) and a Ti silicide film stacked one after another, whereby the sheet resistance can be decreased furthermore.

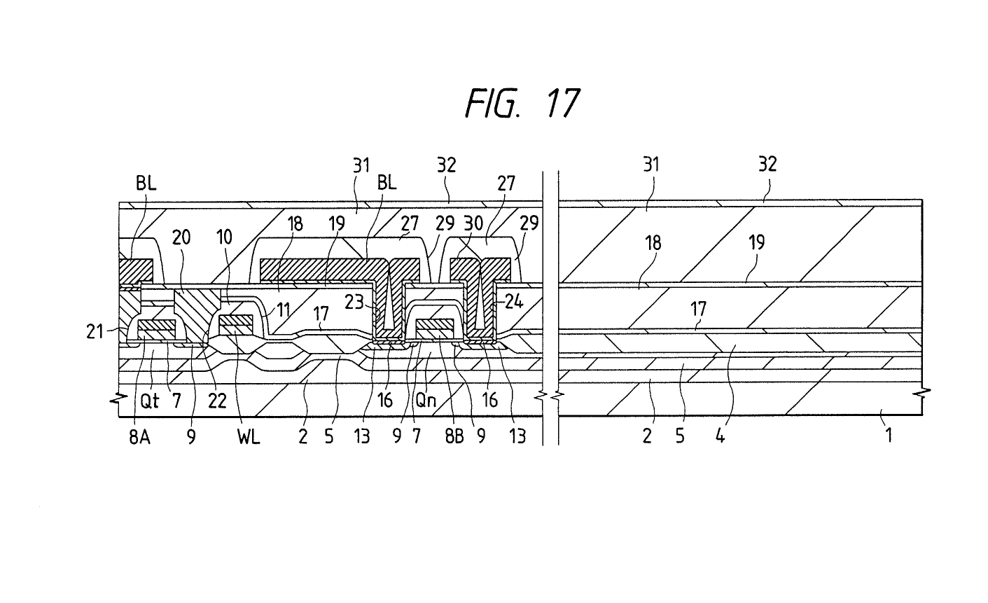

As illustrated in FIG. 17, a side wall spacer 29 is formed on each of the side walls of the bit line BL and the interconnection layer 30 by subjecting the silicon nitride film, which has been deposited by the CVD method, to anisotropic etching, spin coating an SOG film 31 on the bit line BL and the interconnection layer 30 and then depositing thereon a silicon oxide film 32 by the CVD method. It is also possible to use a silicon oxide film having a smaller dielectric constant than a silicon nitride film for the silicon nitride film 27 and the side wall spacer 29. In this case, the parasitic capacity of each of the bit line BL and the interconnection layer 30 can be reduced.

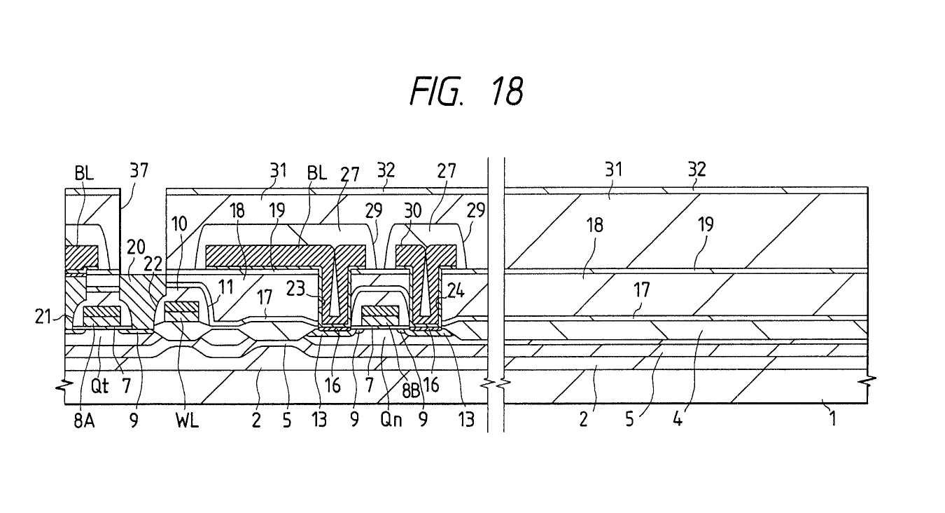

As illustrated in FIG. 18, the silicon oxide film 32 and SOG film 31 are etched with a photoresist as a mask, whereby a connecting hole 37 is formed on the above-described connecting hole 22 formed on the other one of the source region and drain region of MISFETQt for the selection of a memory cell.

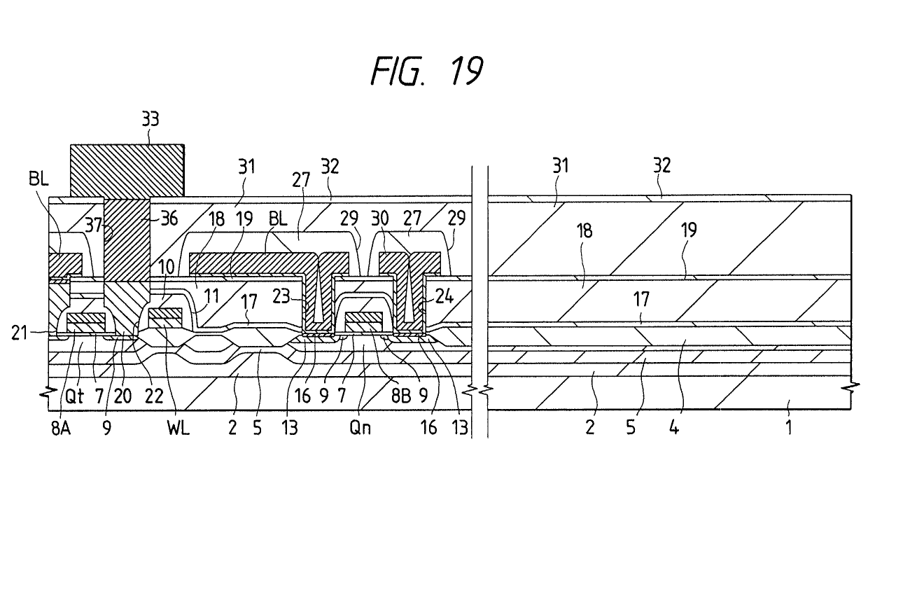

As illustrated in FIG. 19, a W-made plug 36 is embedded inside of the connecting hole 37, followed by the formation of an accumulation electrode 33 for the capacitor C for information storage on the connecting hole 37. The plug 36 is formed by etch back of a W film (or polycrystalline silicon film) which has been deposited on the silicon oxide film 32 by the CVD method. The accumulation electrode 33 is formed by patterning the W film which has been deposited above the sil icon oxide film 32 by the sputtering method, by etching with a photoresist as a mask. The plug 36 may also be formed of a polycrystalline silicon film or a stacked layer of a TiN film and a W film. The accumulation electrode 33 can also be formed of a metal layer or electro-conductive metal oxide layer such as Pt, Ir, IrO₂, Rh, RhO₂, Os, OS0₂, Ru, RuO₂, Re, ReO₃, Pd or Au. In order to increase the capacity of the capacitor C for the information storage, it is effective to enlarge the surface area of the W film by increasing the film thickness of the W film constituting, the accumulation electrode 33.

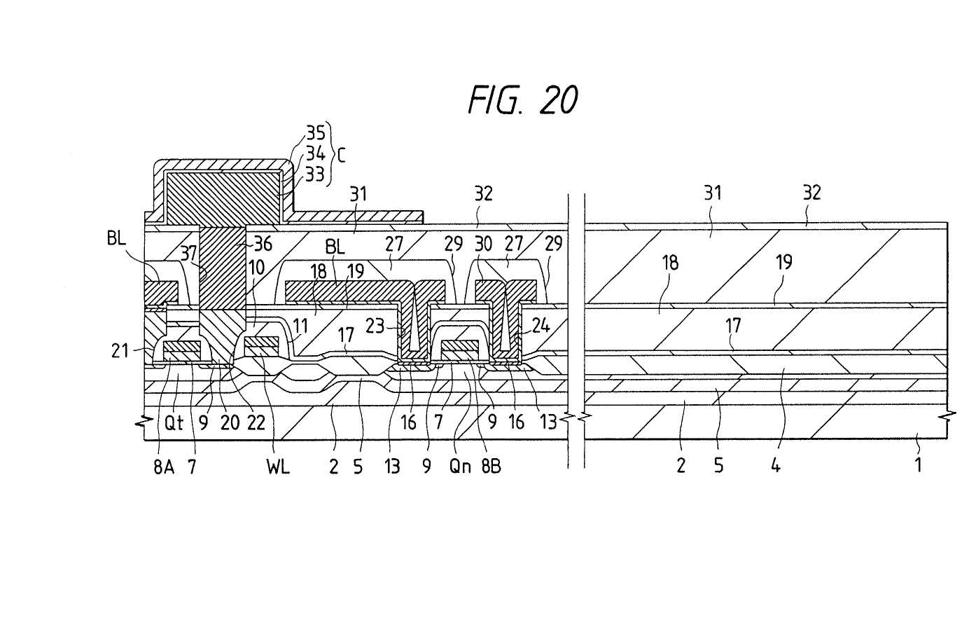

As illustrated in FIG. 20, the capacitor C for the information storage comprising the accumulation electrode 33 made of a W film, a capacitive, insulating film 34 made of a tantalum oxide film, and a plate electrode 35 formed of a TiN film, is formed by depositing a tantalum oxide film on the accumulation electrode 33 by the plasma CVD method, depositing thereon the TiN film by the CVD method and then patterning these layers by etching with a photoresist as a mask. The capacitive insulating layer 34 can also be formed from a high dielectric material such as BST ((Ba, Sr) TiO₃) or a strong dielectric material such as PZT (PbZrₓ, Ti₁₋ₓ, 0₃), PLT (PbLaₓ,Ti₁₋ₓ,O₃), PLZT, PbTiO₃, SrTiO₃, BaTiO₃, PbZrO₃, LiNbO₃, Bi₄Ti₃O₁₂, BaMgF₄ or Y₁, (SrBi₂(Nb, Ta)₂O₉). The plate electrode 35 can also be formed from a metal layer or electro-conductive metal oxide layer such as W silicide/Tin, Ta, Cu, Ag, Pt, Ir, IrO₂, Rh, RhO₂, OS, OSO₂, Ru, RuO₂ Re, ReO₃, Pd or Au.

Since the plate electrode 35 is formed of a TiN film (35A), an excessive increase in the film thickness causes cracks or puts a stress on the capacitive insulating layer 34 below the TiN film, thereby presumably causing deterioration in the properties—Accordingly, the TiN film preferably is relatively thin (about 02 μm).

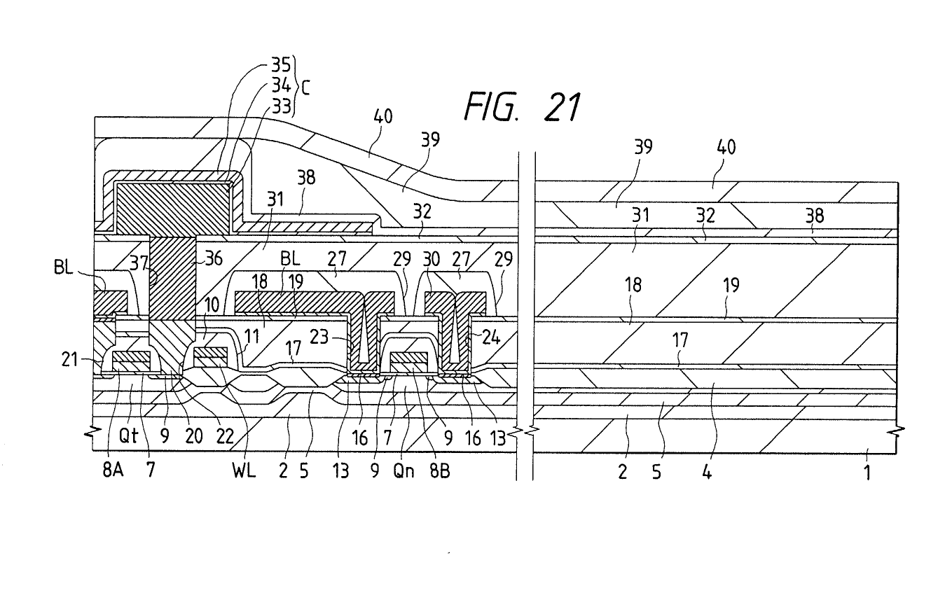

As illustrated in FIG. 21, a step difference between the memory array (MARY) and the peripheral circuit (PC), which difference results from the formation of the capacitor C for information storage, is reduced by depositing a silicon oxide film 38 on the capacitor C for information storage, spin coating an SOG film 39 on the silicon oxide film 38, and then depositing a silicon oxide film 40 on the SOG film 39 by the CVD method. Then, a connecting hole 42 is formed on the plate electrode 35 of the capacitor C for information storage by etching the interlayer insulating film (silicon oxide film 40, SOG film 39, and silicon oxide film 38) with a photoresist as a mask.

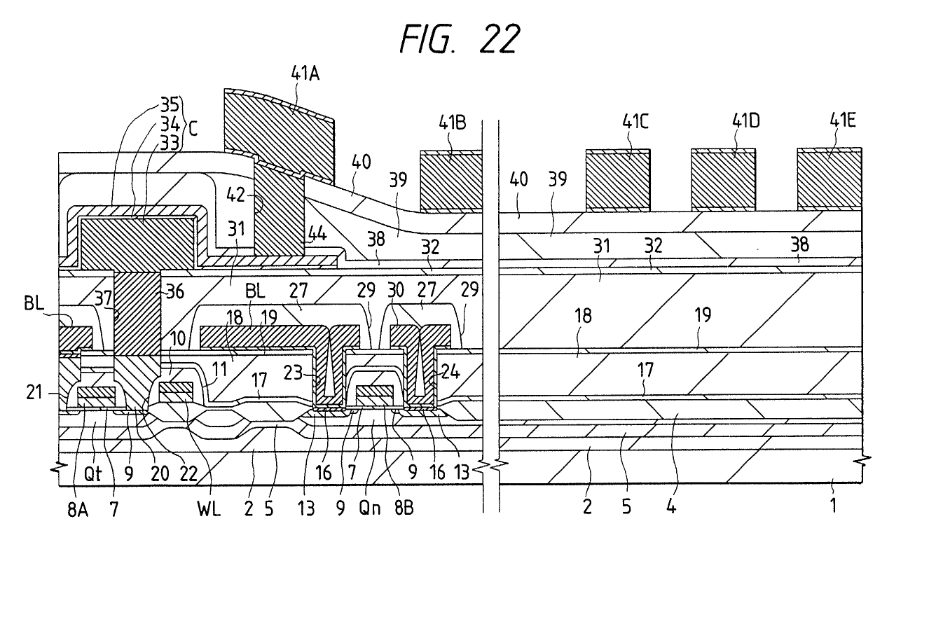

As illustrated in FIG. 22, after a W-made plug 44 is embedded inside of the connecting hole 42, interconnections 41A, 41B and interconnections 41C to 41G (dummy interconnections) are formed on the silicon oxide film 40. The plug 44 is formed by the etch back of a W film deposited on the silicon oxide film 40 by the CVD method. The interconnections 41A to 41G are, on the other hand, formed simultaneously by depositing a TiN film, an Al alloy film and a TiN film on the silicon oxide film 40 by the sputtering method, and then patterning these films by etching with a photoresist as a mask. The interconnections 41A to 41G can also be formed from a stacked layer composed of a TiN film and a Cu film.

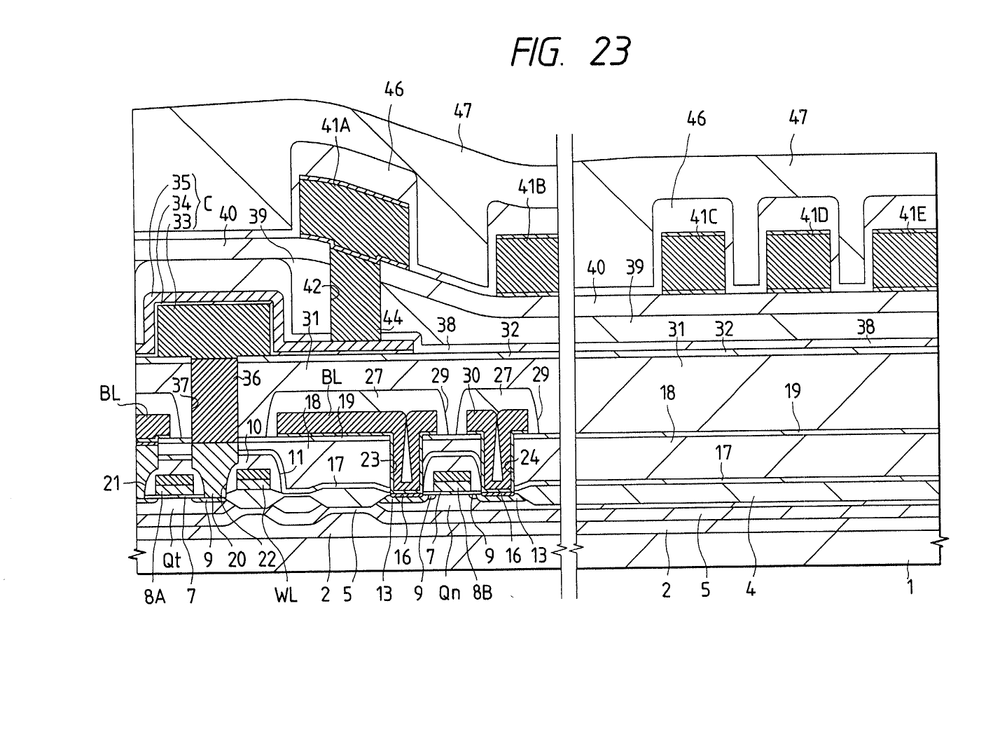

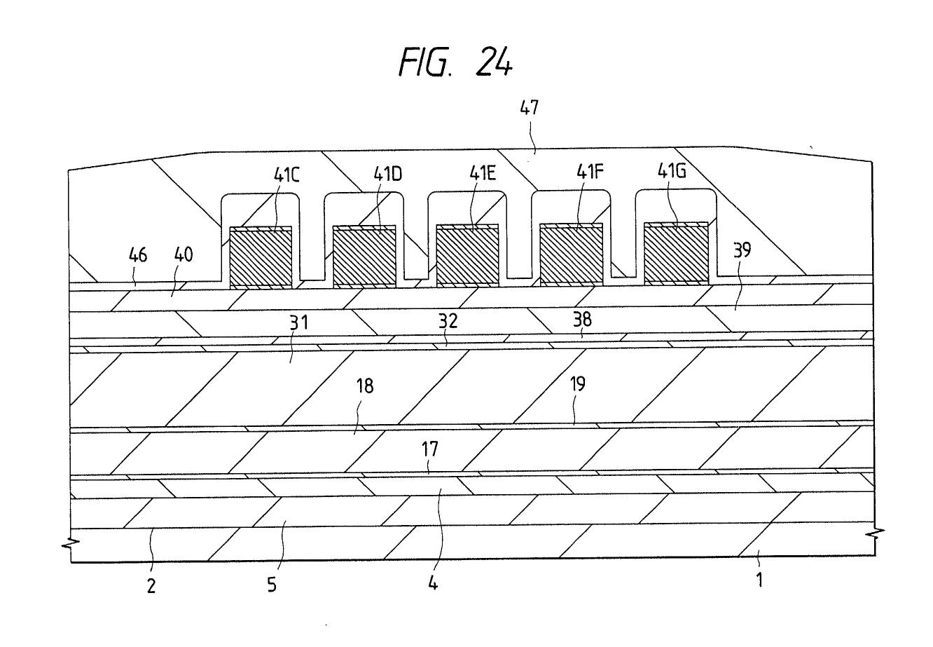

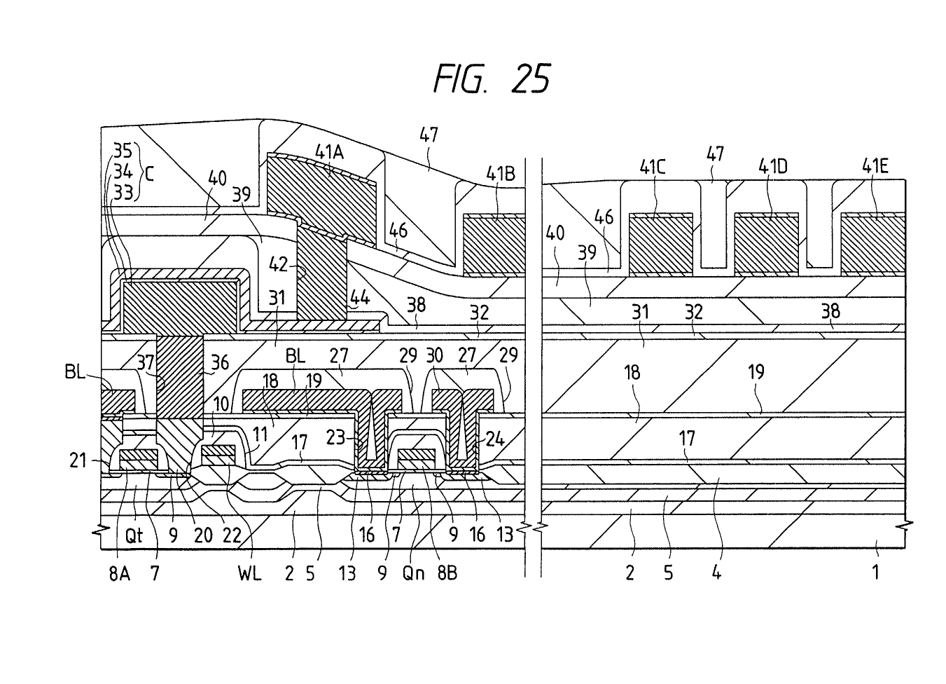

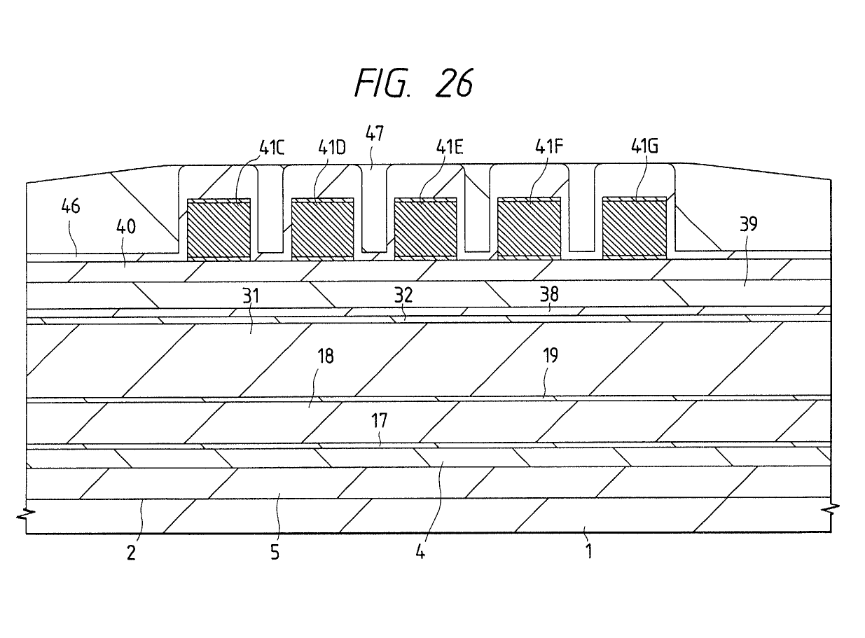

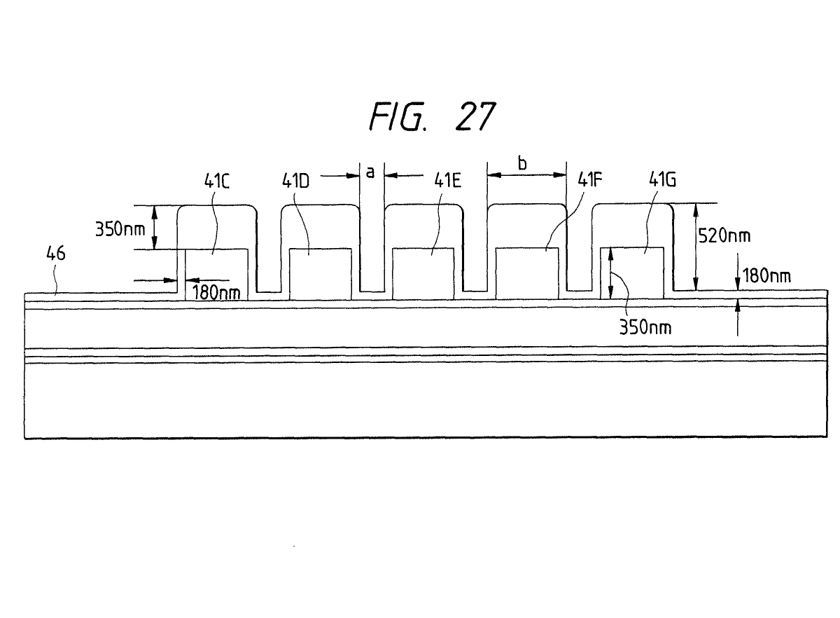

As illustrated in FIGS. 23 and 24, on the interconnections 41A to 41G, a silicon oxide film 46 is then deposited by the CVD method, followed by spin coating an SOG film 47 thereon. As illustrated in FIGS. 25 and 26, in the memory array (MARY), peripheral circuit (PC) and the region for the formation of a pad (BP-A), the SOG film 47 is etched back until the surface portions of the silicon oxide film 46 on the interconnections 41A to 41G are exposed. More specifically, in the memory array (MARY), the interconnections (dummy interconnections) 41C to 41G are disposed so that the SOG film 47 is embedded in a recess portion appearing in a space between the interconnections 41A and 41B and similarly, in the region for the formation of a pad, the SOG film 47 is embedded in the recess portions appearing in the space between two contiguous interconnections of the interconnections 41C to 41G.

Supposing that the film thickness of each of the interconnections 41C to 41G is 350 nm, the film thickness of the silicon oxide film 46 deposited over each of the interconnections 41C to 41G is 180 nm at the flat portion and 350 nm on each of the interconnections 41C to 41G, the film thickness of the SOG film 47 is 250 nm, and the amount of etch back is 160 nm, without the interconnections 41C to 41G, the SOG film 47 of 90 nm, which is calculated simply by subtracting 160 from 250, remains below the bonding pad BP When the bonding pad BP is formed under such a state, peeling tends to occur at the interface with the SOG film 47 due to a strong stress on the bonding pad BP.

In order to avoid the SOG film 47 of 90 nm from remaining on the interconnections 41C to 41G when they are formed below the bonding pad BP, it is necessary, as a countermeasure, to have proper spaces for the interconnections 41C to 41G and embed therein the SOG film 47.

In the case where the film thickness of the silicon oxide film 46 is 180 nm at the flat portion and 350 nm on the interconnections 41C to 41G, there appears a step difference of 520 nm in the space of each of the interconnections 41C to 41G, as illustrated in FIG- 27. Supposing that the space between two contiguous ones of the interconnections 41C to 41G is (a) and the width of each of these interconnections is (b), it is only necessary to specify a and b so that a and b satisfy the following equation:

520×a>(250−160)×(a+b),

that is, b/a<4.78 and to embed the SOG film 47 in the space for the interconnections 41C to 41G.

Accordingly, when the spacing (a) and the width (b) are set at 1 μm and 2 μm, respectively, b/a becomes less than 3.7, which satisfies the above condition (b/a <4.56) so that no SOG film 47 remains on each of the interconnections 41C to 41G.

When the film thickness of each of the interconnections 41C to 41G is set at 610 nm for example, the step difference appearing in the space (a) for the interconnections 41C to 41G becomes 780 nm. It is possible to prevent the SOG film 47 from remaining on the interconnections 41C to 41G by specifying a and b to satisfy b/a<7.7 based on similar calculation. For example, when the spacing (a) and the width (b) are set at 1 μm and 4 μm, respectively, b/a becomes less than 6.8 and satisfies the above condition (b/a<7.7). No SOG film 47 therefore remains on the interconnections 41C to 41G. Even if the film thickness of each of the interconnections 41C to 41G changes, it is possible to prevent the SOG film 47 from remaining on the interconnections 41C to 41G by specifying the spacing (a) and width (b) based on the same manner of thinking.

The structure as described above makes it possible to maintain a large ratio of an area (for example, about 87% of the area of the pad) wherein the silicon oxide film 46 and a silicon oxide film 48 (which will be deposited later) which are composed of the same material, are in a direct contact at their interface, thereby increasing the adhesion of the interlayer insulating film. Even if the bonding pad BP suffers a strong stress, it does not peel easily at the interface with the SOG film 47.

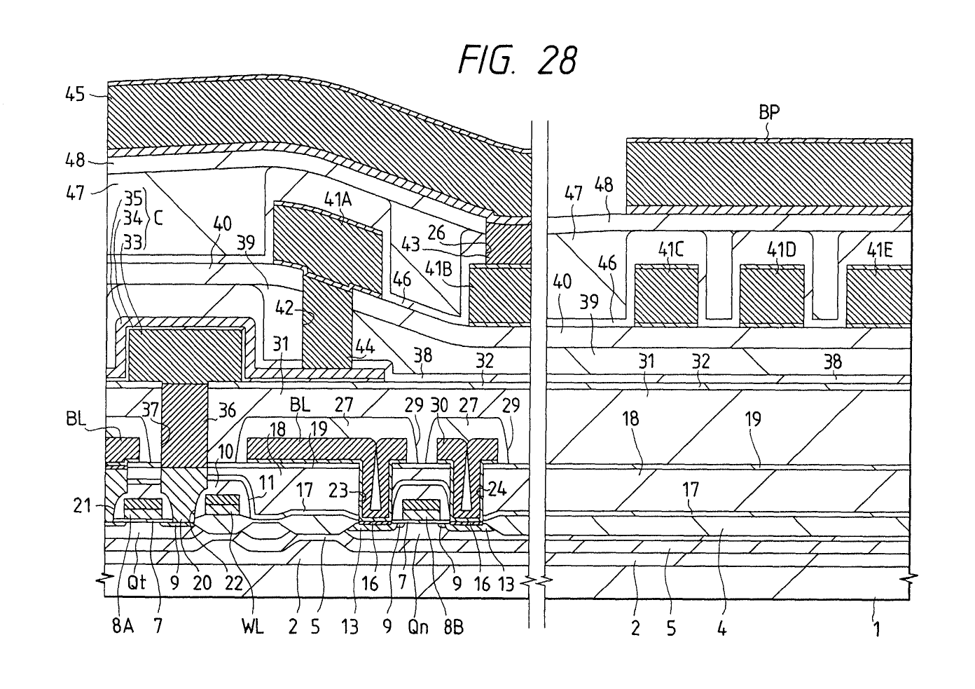

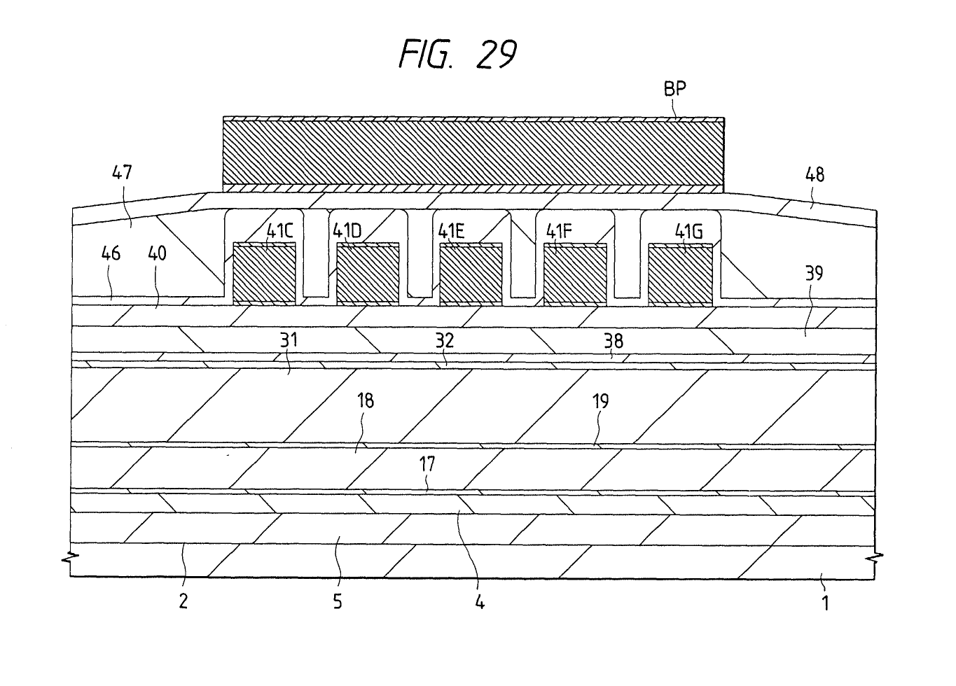

As illustrated in FIGS. 28 and 29, after the silicon oxide film 48 which is the uppermost layer of the interlayer insulating film covering the upper portions of the interconnections 41A to 41G is deposited by the CVD method, the interlayer insulating film (silicon oxide film 46, SOG film 47, and silicon oxide film 48) is etched to form a connecting hole 26 on the interconnection 41B. A W-made plug 43 is then embedded in the connecting hole 26, followed by the formation of the interconnection 45 and bonding pad BP on the intrastratum insulating layer (silicon oxide film 48) The plug 43 is formed by the etch back of the W film which has been deposited over the silicon oxide film 48 by the CVD method The interconnection 45 and bonding pad BP are, on the other hand, formed simultaneously by depositing a TiN film, an Al alloy film, and a TiN film over the silicon oxide film 48 by the sputtering method and then patterning these layers by etching with a photoresist as a mask. It is also possible to constitute the interconnection 45 or bonding pad BP from a stacked layer composed of a TiN film and a Cu film.

After a passivation layer 49 is formed by depositing a layer composed of two films, that is, a silicon oxide film and a silicon nitride film, over the bonding pad BP, the passivation film 49 on the bonding pad BP is removed by etching it with a photoresist as a mask to expose the bonding pad BP, whereby the DRAM according to the embodiment of the present invention as illustrated in FIG. 3 and FIG. 4 is completed.

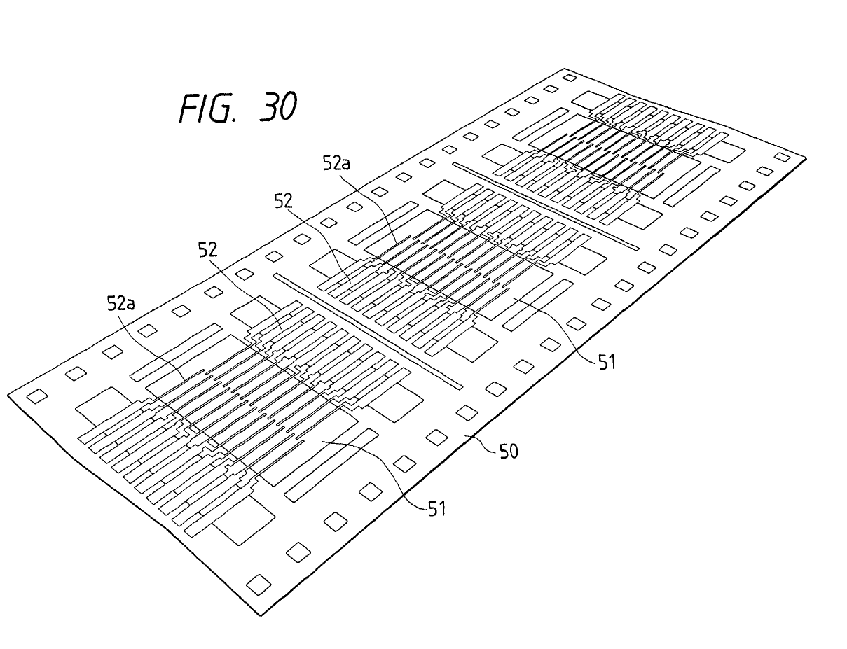

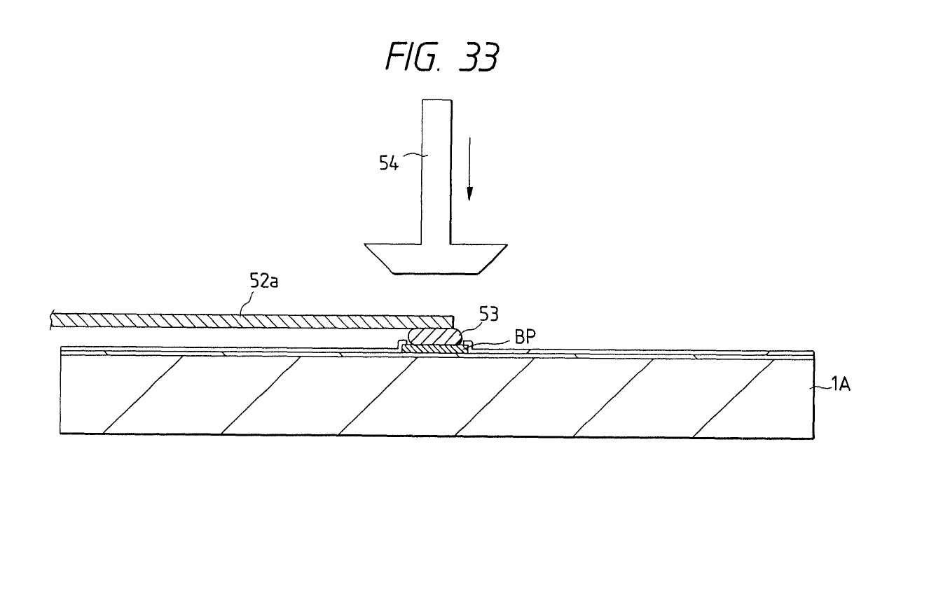

A description will next be made of a process for sealing in a TCP (tape carrier package) the semiconductor chip 1A having the above-described DRAM formed thereon, with reference to FIGS. 30 to 37.

For the fabrication of a TCP, an insulating tape 50 as illustrated in FIG. 30 is prepared first. The insulating tape 50 is composed of a polyimide resin having a thickness of about 50 pm and has, at its center, a rectangular device hole 51 for disposing a semiconductor chip 1A. In the regions extending along two longer sides of the device hole 51, a lead 52 is disposed which has been formed by etching a thin Cu foil adhered on one side of the insulating tape 50, and an inner lead portion 52a of the lead extends in the device hole 51. The insulating tape 50 is a long tape having a length of several tens of meters but only a portion of it (corresponding to three TCPS) is illustrated in FIG. 30.

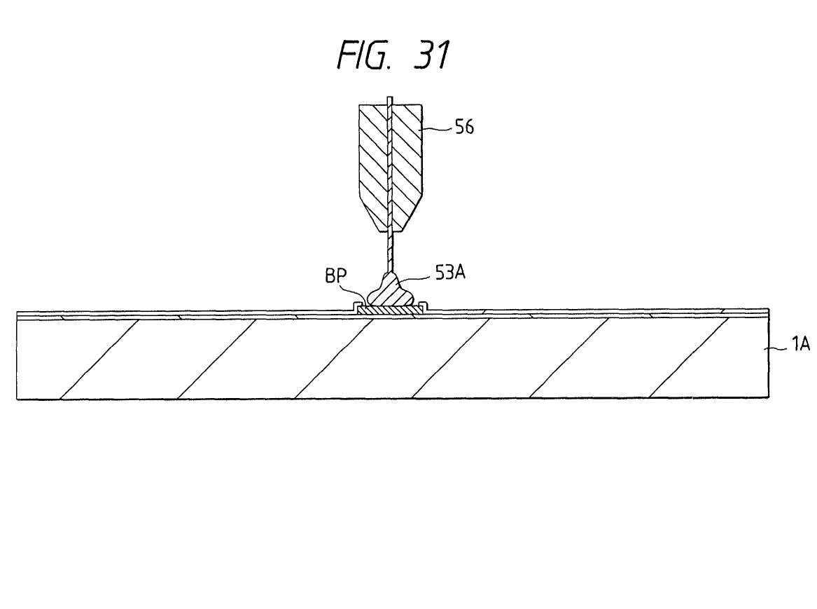

On a bonding pad BP of the semiconductor chip 1A, a bump electrode is formed prior to the fabrication of the TCP. For the formation of the bump electrode, an Au ball 53A is wire-bonded onto the bonding pad BP of the semiconductor chip 1A heated to about 230° C. by using a capillary 56, as illustrated in FIG. 31. At this time, a load of about 45 g is applied to the bonding pad BP.

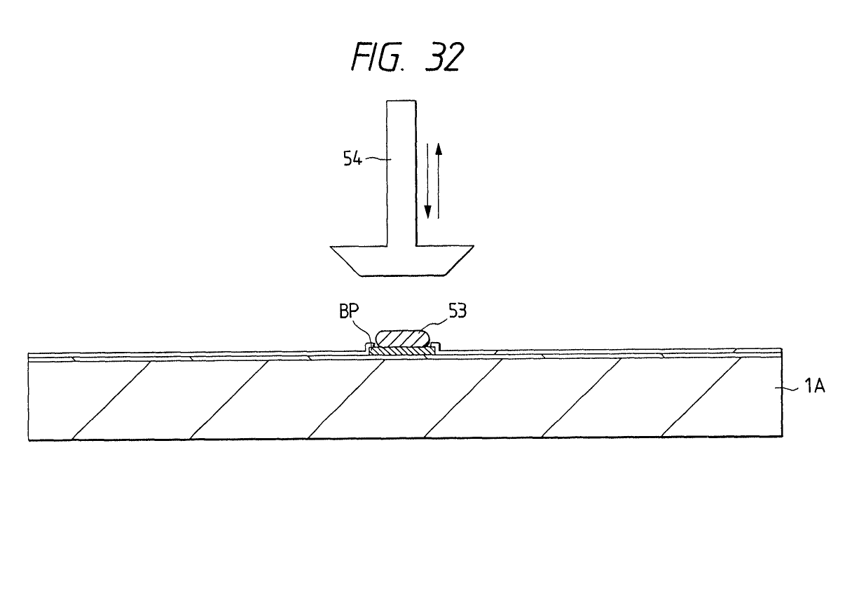

As illustrated in FIG. 32, the bump electrode 53 is then formed by pressing a flat-bottom tool 54 onto the Au ball 53A downwardly to the semiconductor chip 1A, thereby flattening the surface of the ball. The load applied to the bonding pad BP at this time is about 90 g.

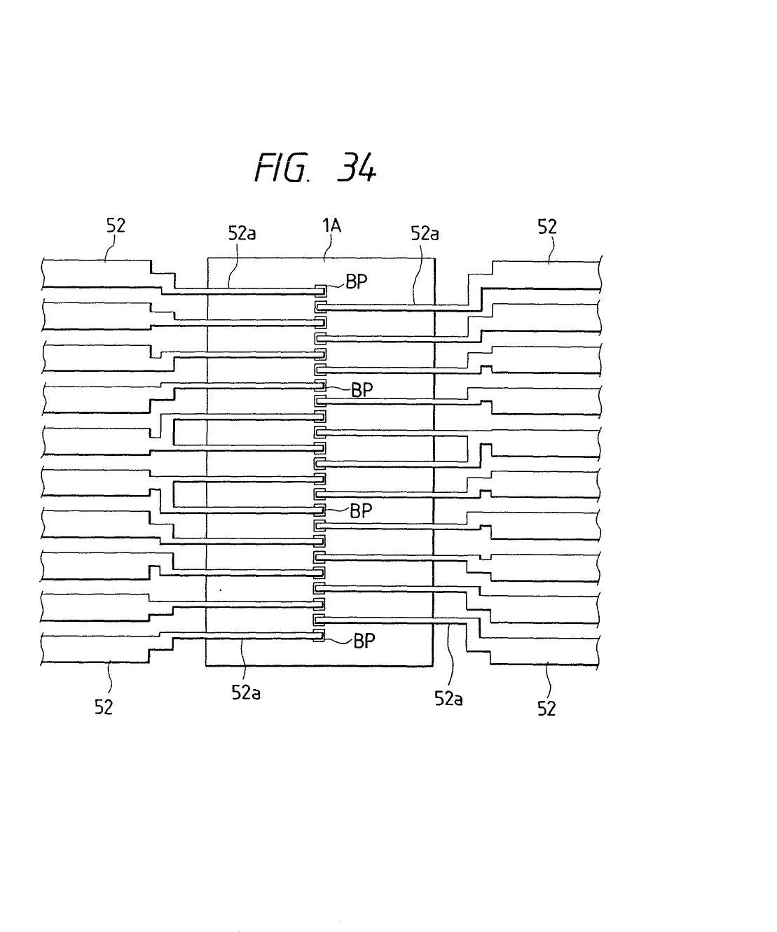

After the inner lead portion 52a of the lead 52 formed on one side of the insulating tape 50 is positioned on the bump electrode 53, the tool 54 heated to about 500° C. is pressed, as illustrated in FIG. 34, onto the inner lead portion 52a for about 1 sec, whereby the inner lead portions 52a of all the leads 52 are bonded simultaneously onto the corresponding bonding pad BP of the semiconductor chip 1A. At this time, the load applied to the bonding pad BP is about 80 g.

In the fabrication step of the TCP according to the embodiment of the present invention, impacts are put on the bonding pad BP three times at the time when the bump electrode 53 is formed on the bonding pad BP of the semiconductor chip 1A and the inner lead portions 52a of the leads 52 are bonded onto the bump electrode 53. As described above, the adhesion of the layers is improved by decreasing the area occupied by the SOG film 47 having relatively low adhesion with the silicon oxide films 46 and 48 and increasing the direct contact area of the silicon oxide films 46 and 48 composed of the same material, among the three films (silicon oxide film 46, SOG film 47, and silicon oxide film 48) constituting the interlayer insulating film below the bonding pad BP, whereby the peeling of the bonding pad BP can be prevented effectively. Also in the memory array (MARY) of the semiconductor chip IA, the direct contact area of the silicon oxide films 46 and 48 is large, while the contact area of the silicon oxide film 46 or 48 with the SOG film 47 is small.

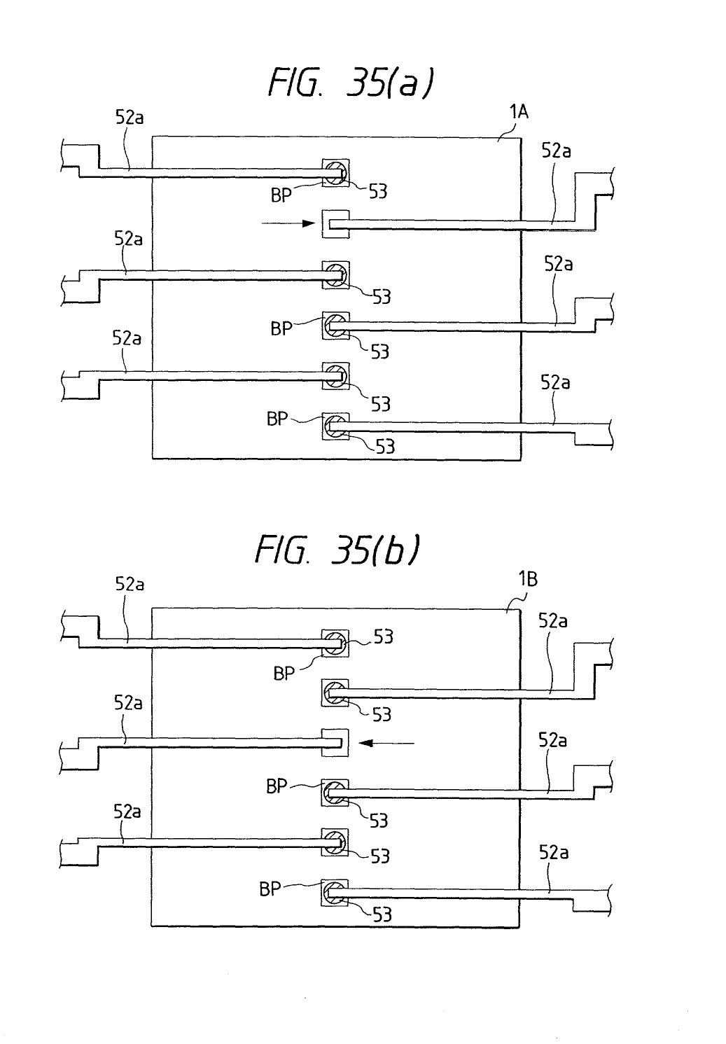

Upon formation of the bump electrode 53, a particular bonding pad BP of the semiconductor chip 1A is allowed to remain free from the formation as illustrated in FIG. 35. The position of the bonding pad BP on which a bump electrode 53 is not formed is made different between the semiconductor chip IA and another semiconductor chip 1B.

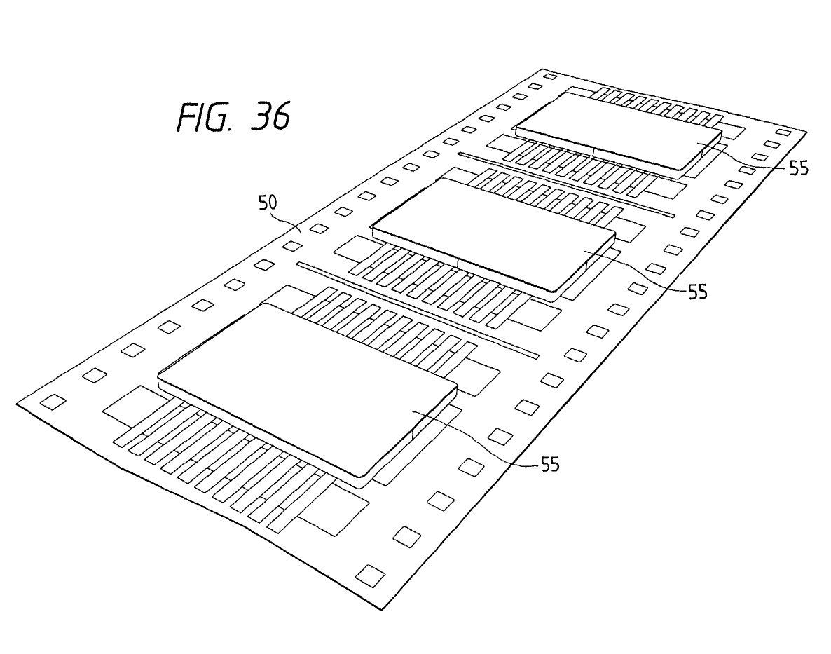

As illustrated in FIG. 36, the principal surface and side surface of the semiconductor chip 1A are sealed with a potting resin 55. The sealing of the semiconductor chip IA with a resin is carried out by applying the potting resin 55 diluted with a thinner onto the principal surface of the semiconductor chip 1A by using a dispenser or the like and then hardening the potting resin 55 by thermal treatment. The semiconductor chip 1A may be sealed with a molding resin.

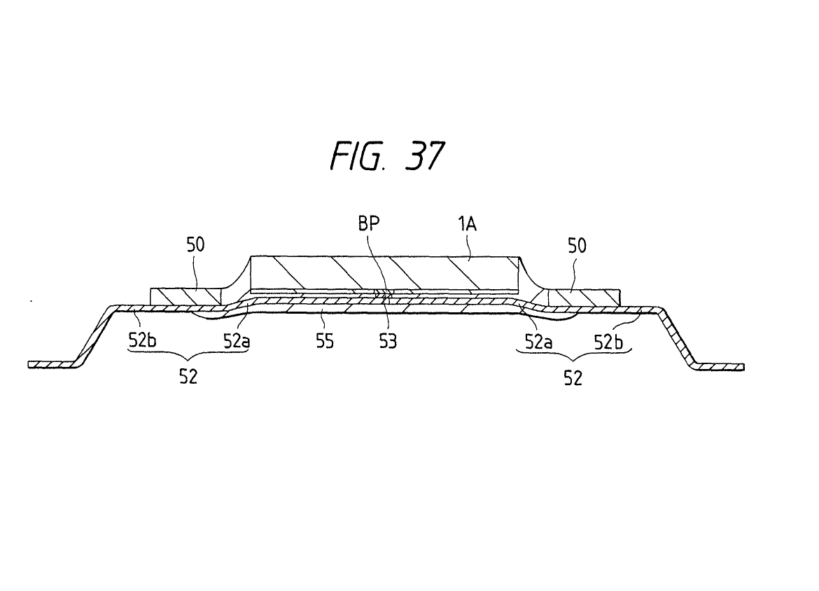

Then, unnecessary portions of the insulating tape 55 and lead 52 are cut and removed, followed by the formation of an outer lead portion 52b of the lead 52 into a shape mountable onto a substrate as illustrated in FIG. 37, whereby the TCP is completed. The outer lead portion 52b is bent toward the principal surface side or the opposite surface side of the semiconductor chip 1A according to the mounting environment of the TCP. The outer lead portion 52b of the lead 52 is plated with solder prior to the formation into the mountable shape

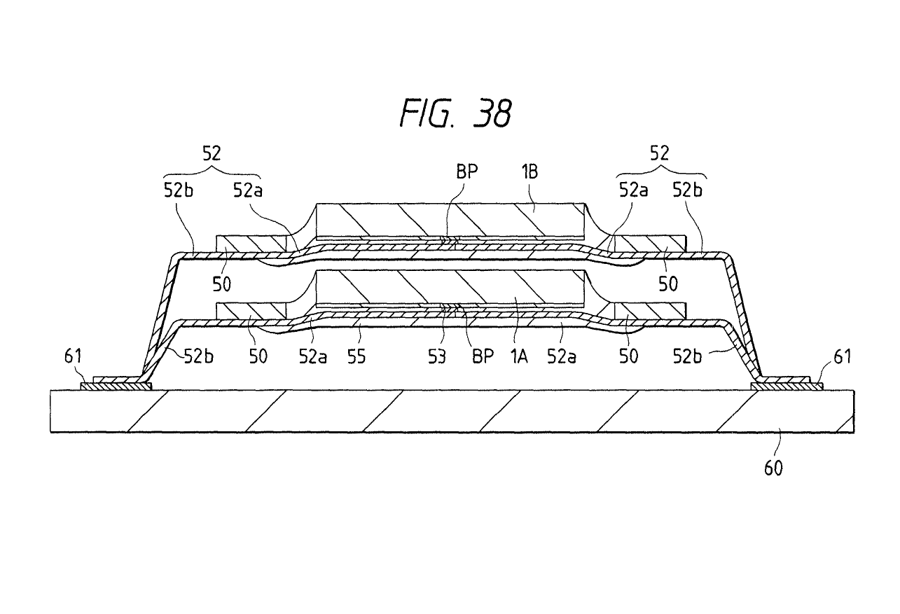

As illustrated in FIG. 38, for mounting of the TCP onto a module substrate 60, the outer lead portion 52b of the lead 52 is positioned onto an electrode 61 of the module substrate 60 and then, the solder on the surface of the outer lead portion 52b is allowed to re-flow in a heating oven. At this time, a stacked memory module can easily be actualized by changing the bent shape of the outer lead portion 52b between the TCP having the semiconductor chip 1A mounted thereon and the TCP having the semiconductor chip 1B mounted thereon.

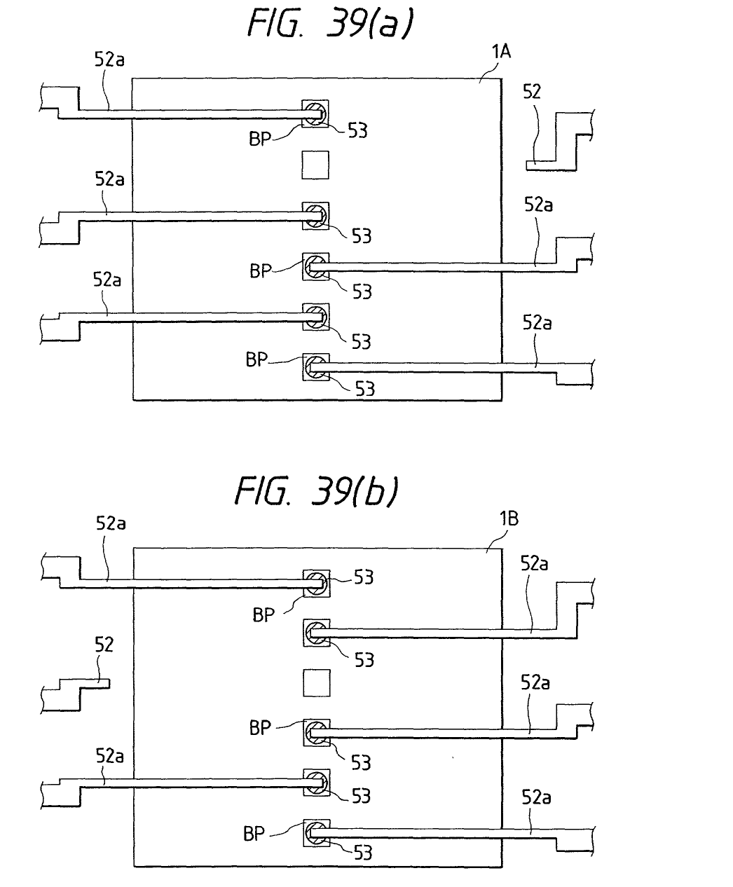

According to this stacked memory module, chip selection can easily be conducted according to the presence or absence of the bump electrode 53 on the particular bonding pad BP, because the position of the bonding pad PD free from the bump electrode 53 is different between the semiconductor chip 1A and the semiconductor chip IB. In this case, as illustrated in FIG. 39, it is also possible to not to form an inner lead portion 52a for a lead 52 corresponding to the bonding pad BP having no bump electrode 53 formed thereon.

By using the TCP according to this embodiment of the present invention, the peeling of the bonding pad BP can be prevented by suppressing a lowering in of the adhesion of the interlayer insulating film (silicon oxide film 46, SOG film 47, and silicon oxide film 48) below the bonding pad BP when the bonding pad BP is subjected to an impact during the step of forming the bump electrode 53 on the bonding pad BP of the semiconductor chip 1A and then bonding the inner lead portion 52b of the lead 52 onto the bump electrode 53.

The present invention conceived by the present inventor has been described specifically with reference to various embodiments but it should be borne in mind that the present invention is not limited to or by the above-described embodiments. It is needless to say that various changes or modifications can be made thereto without departing from the spirit or scope of the invention as set forth herein.

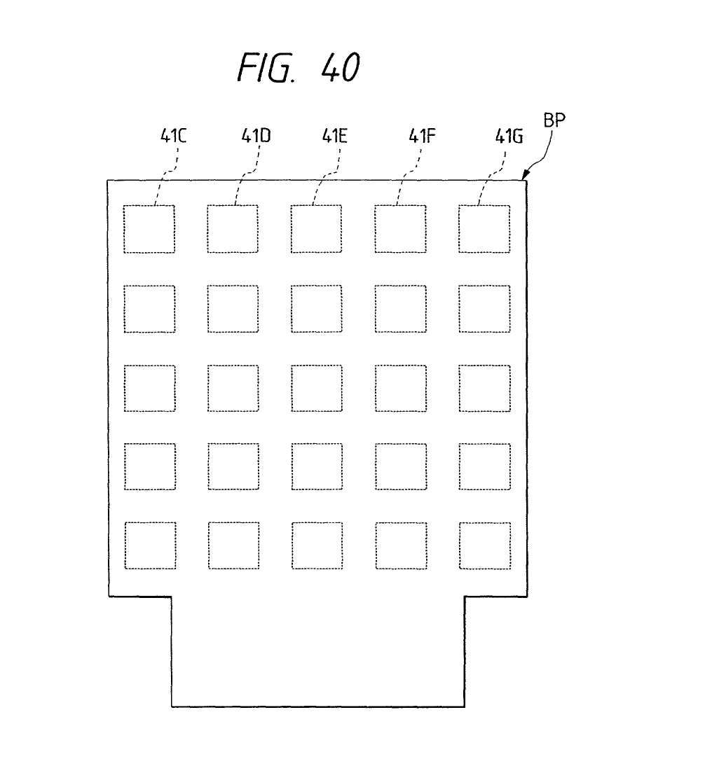

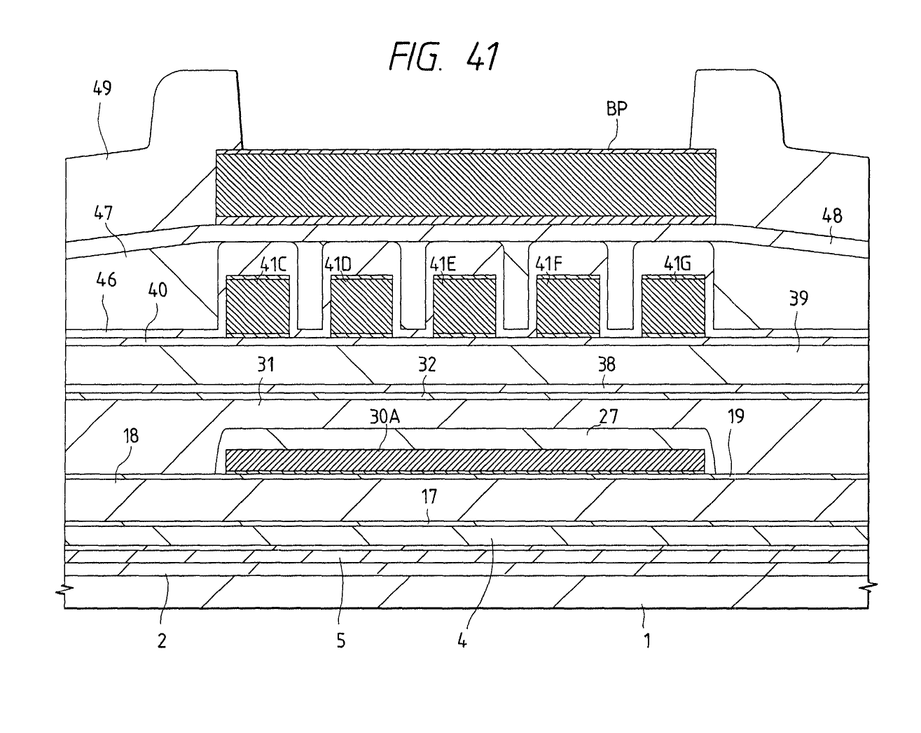

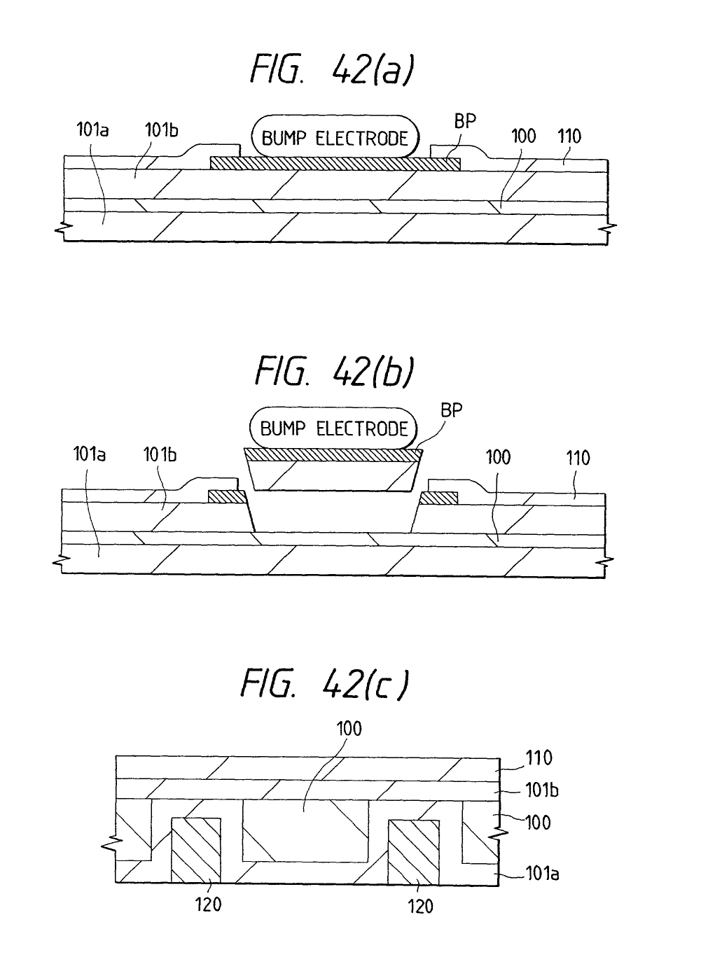

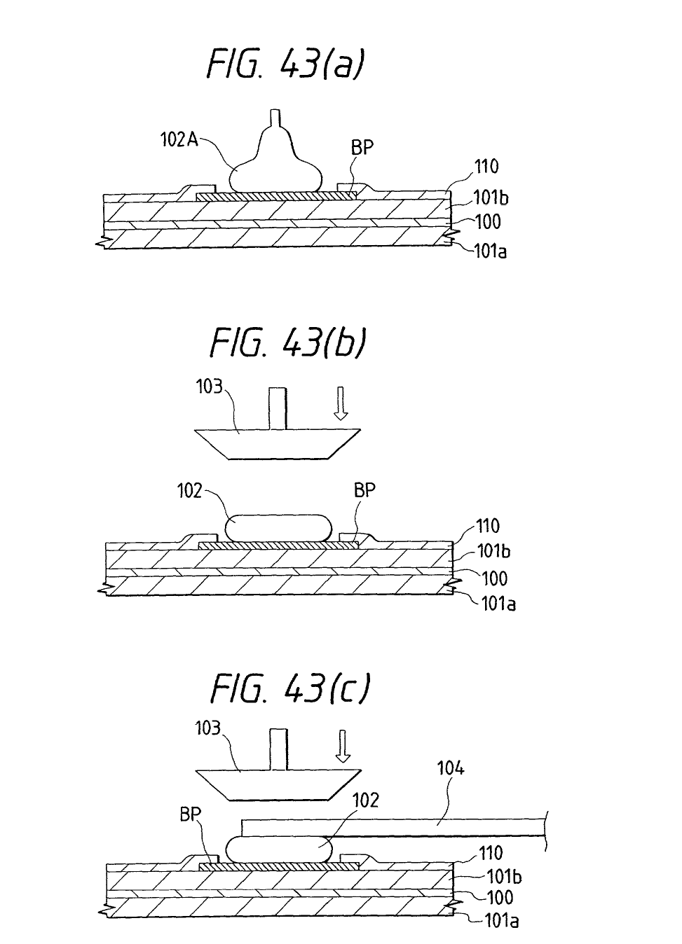

In the above-described embodiment the interconnections (dummy interconnections) below the bonding pad are arranged in the form of a stripe with a predetermined pitch. As illustrated in FIG. 40, interconnections (dummy interconnection) 41C to 41G may be arranged in the form of an island with a predetermined pitch. The arrangement pattern is not limited to a stripe or island so long as no SOG film remains on at least the interconnections (dummy interconnections) when the SOG film is etched back.

As illustrated in FIG. 41, it is also possible to provide an interconnection (dummy interconnection) 30A below the interconnections (dummy interconnections) 410 to 41G that are below the bonding pad. Such an arrangement will make the height of the underground layer of the interconnections (dummy interconnections) 41C to 41G higher than the other region thereby decreasing the film thickness of the SOG film 47 on the interconnections (dummy interconnections) 41C to 41G upon spin coating of the SOG film 47. Accordingly, a portion of the SOG film 47 on each of the interconnections (dummy interconnections) 41C to 41G can be removed in a short time when the SOG film 47 is etched back.

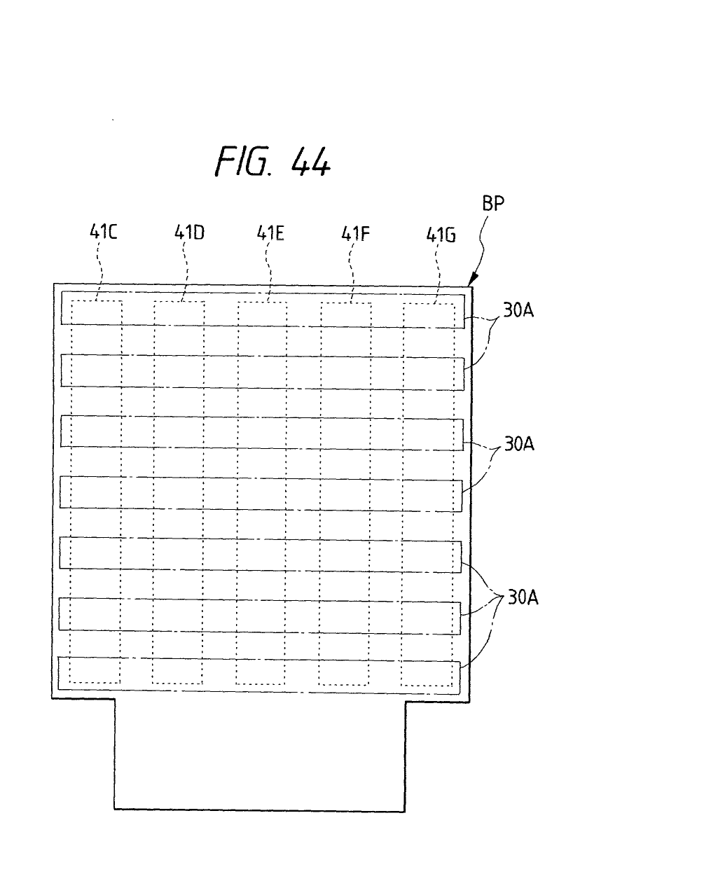

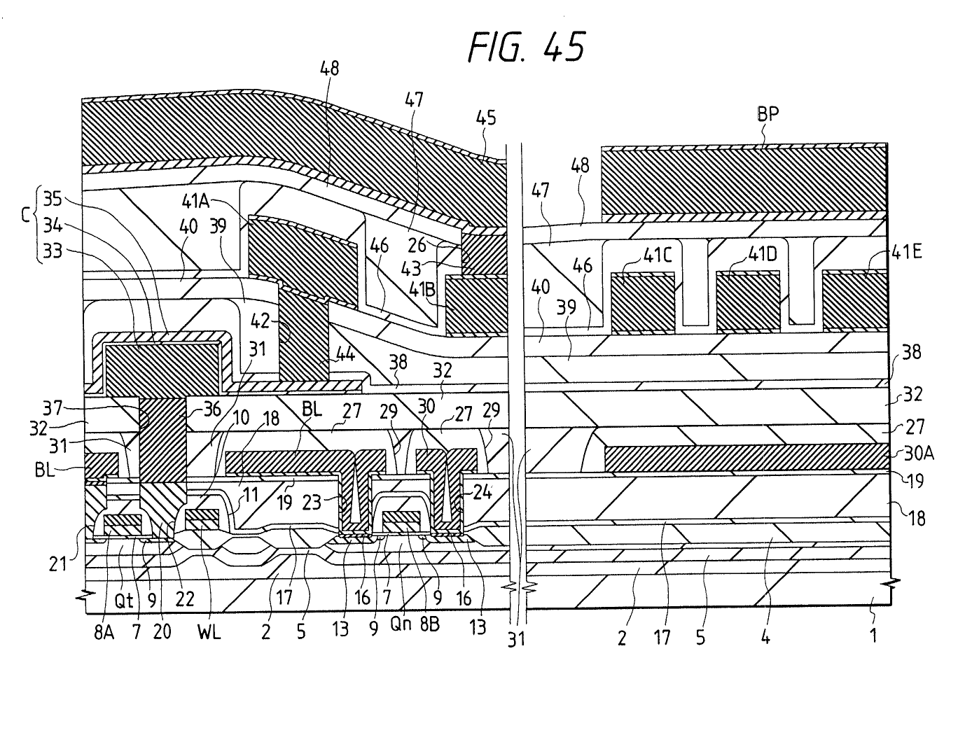

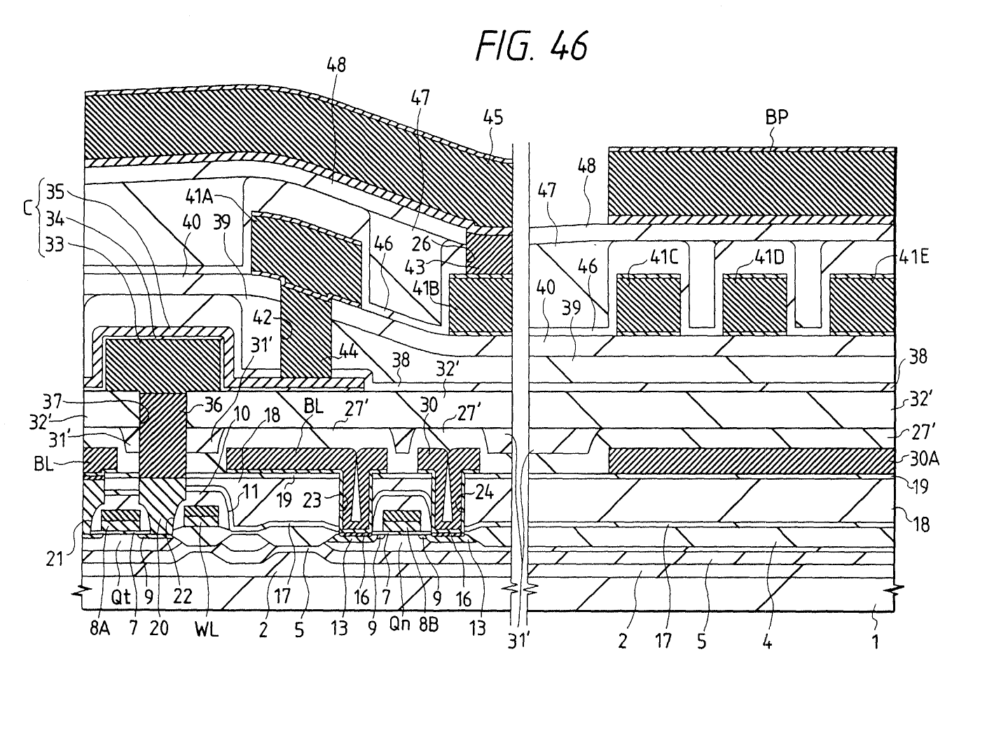

FIG. 44 illustrates one example of the plane layout of the dummy interconnection 30A of FIG. 41, while FIG. 45 is a fragmentary cross-sectional view of FIG. 44. In this example, an SOG film 31 is embedded in a silicon oxide film 27 and is formed so as to be brought into contact with a the silicon oxide film 32 on the interconnection 30A, which brings about an improvement in the adhesion of the interlayer insulating film below the bonding pad BP. Incidentally, as illustrated in FIG. 44, the dummy interconnection 30A extends in a direction vertical to the extending direction of each of the dummy interconnections 41C, 41D, 41E, 41F, and 41G. As illustrated in FIG. 46, an interlayer insulating film composed of 27′, 31′, and 32′ on the first interconnection layers 30 and 30′ may have constitution similar to the interlayer insulating film composed of three films (silicon oxide film 46, SOG film 47, and silicon oxide film 48). Described specifically, it is possible to form the interlayer insulating film by depositing the silicon oxide insulating film 27′ by the CVD method, embedding an SOG film 31′ in a recess portion of the insulating film 27′, and bringing the silicon oxide film 27′, into contact with the silicon oxide film 32′ over the dummy interconnection 30A′ and interconnection 30.

Incidentally, FIG. 41 and FIGS. 44 to 46 illustrate a case where the interconnection (dummy interconnection) 30A below the interconnections (dummy interconnections) 41C to 41G is formed similarly to the bit line BL or interconnection 30. Alternatively, it is possible to form it similarly to the gate electrodes 8A and 8B, accumulation electrode (lower electrode) 33 or plate electrode (upper electrode) 35. At this time, at least two interconnections (dummy interconnections) may be disposed below the interconnections (dummy interconnections) 41C to 41G. In addition, the interconnection formed below the bonding pad is not always a dummy interconnection under the electrically floating state, but an actual interconnection partially extended or branched.

In the above embodiment, a description was made of the case where a semiconductor chip having a DRAM formed thereon is sealed in a TCP. The present invention can be applied to at least the case where a semiconductor chip, having, below a bonding pad, an intrastratum insulating layer containing an SOG film, is sealed in TCP.

The present invention is not limited to a TCP, but can be applied to at least an LSI package which electrically connects a lead and a bonding pad through a bump electrode formed on a bonding pad of a semiconductor chip.

Furthermore, the present invention is not limited to an interlayer insulating film containing an SOG film, but can be applied to an LSI package, wherein a bonding pad is formed on an interlayer insulating film formed by stacking different insulating materials, and the bonding pad so obtained and a lead are electrically connected through a bump electrode formed on the bonding pad.

Among the features disclosed by the present application, advantages resulting from representative features will next be described simply.

According to the present invention, it is possible to effectively prevent the peeling of a bonding pad which otherwise occurs during the step of sealing the semiconductor chip in a TCP, the semiconductor chip having two vertical interconnections flattened therebetween by an insulating film containing an SOG film so that the reliability and yield of the TCP, particularly a TCP fabricated by the “post-step bump method”, can be improved.

According to the present invention, a dummy interconnection is formed below the bonding pad simultaneously with the formation of an interconnection on the principal surface of a semiconductor chip, which makes it possible to bring about the above-described advantages without increasing the number of steps for the prior process (wafer process).

What is claimed is:

1. A semiconductor integrated circuit device comprising an interlayer insulating film formed on a principal surface of a semiconductor chip, said interlayer insulating film containing at least a stacked film comprised of a first silicon oxide film, a spin-on-glass film and a second silicon oxide film, and a bonding pad formed on said interlayer insulating film, wherein a plurality of interconnections has been disposed below said bonding pad through said interlayer insulating layer at a predetermined pitch and at least a portion of said spin-on-glass film on each of said plurality of interconnections has been removed.

2. A semiconductor integrated circuit device according to claim 1, wherein said plurality of interconnections have been arranged in a pattern extending in parallel to each other.

3. A semiconductor integrated circuit device according to claim 1, wherein said plurality of interconnections have been arranged in a pattern separated from each other as an island.

4. A semiconductor integrated circuit device according to claim 1, wherein said plurality of interconnections are dummy ones in an electrically floating state.

5. A semiconductor integrated circuit device according to claim 1, wherein a second interconnection has been disposed below said plurality of interconnections through a second intrastratum insulating layer.

6. A semiconductor integrated circuit device according to claim 1, wherein said spin-on-glass film has been embedded in a space region between two adjacent interconnections of said plurality of interconnections.

7. A semiconductor integrated circuit device which comprises a memory cell of a DRAM in a first region on a principal surface of a semiconductor chip, said memory cell of the DRAM being formed of a MISFET for the selection of a memory cell and a capacitor element for the information storage disposed thereon; an interlayer insulating film containing at least a stacked film comprised of a first silicon oxide film, a spin-on-glass film, and a second silicon oxide film formed on said capacitor element for the information storage; and a bonding pad formed on said interlayer insulating film in a second region of said principal surface of the semiconductor chip, wherein a plurality of interconnections have been disposed below said bonding pad through said interlayer insulating film at a predetermined pitch and at least a portion of said spin-on-glass film on each of said plurality of interconnections has been removed.

8. A tape-carrier-package type semiconductor integrated circuit device wherein one end portion of a lead is bonded through a bump electrode onto said bonding pad of the semiconductor chip as claimed in claim 1.

9. A process for the fabricating a semiconductor integrated circuit device, comprising the steps of:
(a) forming a semiconductor element in a first region on a principal surface of a semiconductor chip;
(b) forming one or more interconnection layers on said semiconductor element through at least one interlayer insulating film;
(c) forming an uppermost interconnection layer of said one or more interconnection layers and disposing a plurality of interconnections in a second region on said principal surface of the semiconductor chip at a predetermined pitch;
(d) depositing a first silicon oxide film on said uppermost interconnection layer including said plurality of interconnections and then applying a spin-on-glass film above said silicon oxide film;
(e) removing at least a portion of said spin-on-glass film on each of said plurality of interconnections by etch back of said spin-on-glass film; and
(f) depositing a second silicon oxide film on said principal surface of the semiconductor chip, patterning an electro-conductive layer deposited on said second silicon oxide film, thereby forming a bonding pad on said plurality of interconnections.

10. A process according to claim 9, wherein said plurality of interconnections are arranged in a pattern extending in parallel to each other.

11. A process according to claim 9, wherein said plurality of interconnections are arranged in a pattern separated from each other as an island.

12. A process according to claim 9, wherein said plurality of interconnections form dummy ones in an electrically floating state.

13. A process according to claim 9, wherein one or more interconnection layers are formed below said bonding pad in said step (b).

14. A process for the fabricating a semiconductor integrated circuit device, comprising the steps of:
(a) depositing a first electro-conductive layer on a principal surface of a semiconductor chip, forming a gate electrode of a MISFET for the selection of a memory cell which constitutes a portion of a memory cell of a DRAM in a first region on said principal surface of the semiconductor chip by patterning said first electro-conductive layer, and forming a gate electrode for a MISFET constituting a peripheral circuit of said DRAM in a second region on said principal surface of the semiconductor chip;
(b) depositing a second electro-conductive layer on said MISFET for the selection of a memory cell and said MISFET of the peripheral circuit through a first insulating film, and patterning said second electro-conductive layer, thereby forming a bit line connected with either one of a source region or a drain region of said MISFET for the selection of a memory cell and a first interconnection layer of the peripheral circuit connected with either one of a source region or a drain region of said MISFET of the peripheral circuit;
(c) depositing a third electro-conductive layer on said bit line and said first interconnection layer through a second insulating film and then patterning said third electro-conductive layer, thereby forming a lower electrode of a capacitor for the information storage which is connected with the other one of said source region and said drain region of MISFET for the selection of a memory cell;
(d) depositing a fourth electro-conductive layer above said lower electrode of the capacitor for the information storage through a third insulating film and then patterning said fourth electro-conductive layer and said first insulating film, thereby forming an upper electrode and capacitive insulating layer for said capacitor for the information storage;
(e) depositing a fifth electro-conductive layer above said capacitor for the information storage through a fourth insulating film and then patterning said fifth electro-conductive film, thereby forming an interconnection connected with said upper electrode of the capacitor for the information storage and a second interconnection layer of the peripheral circuit;
(f) patterning said fifth electro-conductive layer in said step (e), thereby disposing a plurality of interconnections in a third region on said principal surface of the semiconductor chip at a predetermined pitch;
(g) depositing a first silicon oxide film on said interconnection connected with the upper electrode of the capacitor for the information storage, said second interconnection layer of the peripheral circuit, and said plurality of interconnections and then applying a spin-on-glass film over said first silicon oxide film;
(h) removing at least a portion of said spin-on-glass film on each of said plurality of interconnections by etch back of said spin-on-glass film; and
(i) depositing a second silicon oxide film on said principal surface of the semiconductor chip and then patterning a sixth electro-conductive layer deposited over said second silicon oxide film, thereby forming a bonding pad on said plurality of interconnections.

15. A process according to claim 14, wherein at least one electro-conductive layer of said first to fourth electro-conductive layers is patterned and one or more interconnection layers are formed below said bonding pad.

16. A process for the fabricating a tape-carrier-package type semiconductor integrated circuit device, comprises the steps of:
(a) preparing a semiconductor chip as claimed in any one of claims 1 to 7 and an insulating tape having a lead formed on at least one side thereof;
(b) wire bonding a metal ball onto said bonding pad of the semiconductor chip;
(c) flattening a surface of said metal ball, thereby forming a bump electrode on said bonding pad; and
(d) bonding one end portion of said lead formed on the insulating tape onto said bump electrode.

17. A multi-chip module type semiconductor integrated circuit device, which is obtained by stacking a plurality of tape-carrier-package type semiconductor integrated circuit devices obtained according to the process claimed as claim 16 and then mounting on a printed circuit board.

18. A semiconductor integrated circuit device which comprises an interlayer insulating film containing at least a stacked film composed of a first insulating film, a flattened film, and a second insulating film; and a bonding pad formed on said interlayer insulating film, wherein a plurality of interconnections have been disposed below said bonding pad through said interlayer insulating film; said first insulating film and said second insulating film are formed to be brought into contact on at least said plurality of interconnections; and the adhesion between said first insulating film and said second insulating film is larger than that between said first or second insulating film and said flattened film.

19. A semiconductor integrated circuit device according to claim 18, wherein said first insulating film and said second insulating film are formed of the same insulating material.
